(19) United States
(12) Patent Application Publication
(10) Pub. No.: US 2025/0359463 A1
(43) Pub. Date: Nov. 20, 2025

(54) DISPLAY PANEL, ELECTRONIC DEVICE AND METHOD FOR MANUFACTURING THE DISPLAY PANEL

(71) Applicant: Samsung Display Co., Ltd., Yongin-si (KR)

(72) Inventor: HYUNEOK SHIN, Yongin-si (KR)

(21) Appl. No.: 19/085,905

(22) Filed: Mar. 20, 2025

(30) Foreign Application Priority Data
May 16, 2024 (KR) 10-2024-0063876

(51) Int. Cl. H10K 59/80; H10K 59/12; H10K 59/122; H10K 71/60; H10K 102/00

(52) U.S. Cl. CPC H10K 59/80522; H10K 59/1201; H10K 59/122; H10K 71/60; H10K 2102/351

(57) ABSTRACT

A display panel includes a base layer, a pixel defining layer which is provided on the base layer and in which a light emitting opening is defined, an auxiliary electrode which is provided on the pixel defining layer and in which an auxiliary electrode opening overlapping the light emitting opening is defined, and a light emitting element including an anode provided on the base layer and having at least a portion exposed by the light emitting opening, a cathode provided on the auxiliary electrode and the anode, and a light emitting pattern provided between the anode and the cathode and overlapping the light emitting opening. The auxiliary electrode and the light emitting pattern are in direct contact with each other.

### CROSS-REFERENCE TO RELATED APPLICATION

The present application claims priority to and the benefit of Korean Patent Application No. 10-2024-0063876, filed on May 16, 2024, in the Korean Intellectual Property Office, the entire content of which is incorporated herein by reference.

### BACKGROUND

One or more aspects of embodiments of the present disclosure herein are directed toward a display panel, electronic device and a method for manufacturing the display panel. For example, they are directed toward a display panel with improved display quality.

Display devices such as televisions, monitors, smartphones, and/or tablet computers, which provide images for users, include display panels that display the images. Various display panels such as liquid crystal display panels, organic light emitting display panels, electro wetting display panels, and/or electrophoretic display panels, have been developed.

An organic light emitting display panel may include an anode, a cathode, and a light emitting pattern. The light emitting pattern may be separated for each light emitting area (e.g., each light emitting area may include a separate light emitting pattern), and the cathode may supply a common voltage to each light emitting area.

### SUMMARY

One or more aspects of embodiments of the present disclosure are directed toward a display panel with improved display quality, which provides a light emitting element without using a metal mask (e.g., excluding a metal mask), and a method for manufacturing the display panel.

Additional aspects will be set forth in part in the description which follows and, in part, will be apparent from the description, or may be learned by practice of the presented embodiments of the disclosure.

One or more embodiments of the disclosure provide a display panel including a base layer, a pixel defining layer which is arranged on the base layer and in which a light emitting opening is defined, an auxiliary electrode which is arranged on the pixel defining layer and in which an auxiliary electrode opening overlapping the light emitting opening is defined, and a light emitting element including an anode arranged on the base layer and having at least a portion exposed by the light emitting opening, a cathode arranged on the auxiliary electrode and the anode, and a light emitting pattern arranged between the anode and the cathode and overlapping the light emitting opening. The auxiliary electrode and the light emitting pattern are in direct contact with each other.

In one or more embodiments, the cathode may be in direct contact with the auxiliary electrode.

In one or more embodiments, the cathode may entirely cover a top surface of the auxiliary electrode.

In one or more embodiments, the light emitting pattern may be arranged in the auxiliary electrode opening.

In one or more embodiments, a thickness of the auxiliary electrode may be greater than a thickness of the cathode, and the auxiliary electrode may include at least one selected from among copper (Cu), aluminum (Al), titanium (Ti), molybdenum (Mo), indium tin oxide (ITO), and indium zinc oxide (IZO).

In one or more embodiments, the auxiliary electrode may have higher conductivity than at least the cathode.

In one or more embodiments, the display panel may further include an inorganic encapsulation film arranged on the cathode.

In one or more embodiments, the auxiliary electrode opening may include a first surface and a second surface that have different widths in a cross-section. The first surface may be arranged on the second surface, and the width of the second surface may be greater than the width of the first surface.

In one or more embodiments, the first surface of the auxiliary electrode opening may be spaced and/or apart (e.g., spaced apart or separated) from the light emitting pattern.

In one or more embodiments, the light emitting pattern may be in contact with a portion of the second surface.

In one or more embodiments, a groove overlapping the pixel defining layer may be defined in a top surface of the auxiliary electrode.

In one or more embodiments, the first surface may be a side surface of a tip protruding from the second surface toward a center of the auxiliary electrode opening.

In one or more embodiments, the tip may overlap the light emitting pattern.

In one or more embodiments, the light emitting element may be provided in plurality, and the plurality of light emitting elements may include a first light emitting element in which a first light emitting area that is to emit light having a first color is defined, a second light emitting element in which a second light emitting area that is to emit light having a second color different from the first color is defined, and a third light emitting element in which a third light emitting area that is to emit light having a third color different from the first color and the second color is defined. The light emitting opening may be provided in plurality, and the plurality of light emitting openings may include a first light emitting opening overlapping the first light emitting area, a second light emitting opening overlapping the second light emitting area, and a third light emitting opening overlapping the third light emitting area. The auxiliary electrode opening may be provided in plurality, and the plurality of auxiliary electrode openings may include a first auxiliary electrode opening overlapping the first light emitting opening, a second auxiliary electrode opening overlapping the second light emitting opening, and a third auxiliary electrode opening overlapping the third light emitting opening.

In one or more embodiments of the disclosure, a method for manufacturing a display panel includes forming a preliminary pattern including an anode, a light emitting pattern, and a sacrificial pattern on a base layer, forming an auxiliary electrode layer on a pixel defining layer and the sacrificial pattern, forming a photoresist layer on the auxiliary electrode layer, etching the auxiliary electrode layer to form an auxiliary electrode, removing the photoresist layer, removing the sacrificial pattern, depositing a cathode on a top surface of each of the light emitting pattern and the auxiliary electrode, and forming an inorganic encapsulation film on the cathode.

In one or more embodiments, in the forming of the preliminary pattern, the sacrificial pattern may be formed through the same process as the light emitting pattern.

In one or more embodiments, in the forming of the preliminary pattern, a side surface of the sacrificial pattern and a side surface of the light emitting pattern may be aligned with each other.

In one or more embodiments, in the forming of the auxiliary electrode layer, a metal constituting the auxiliary electrode layer may have a different etch rate from a metal constituting the sacrificial pattern.

In one or more embodiments, in the forming of the photoresist layer, the photoresist layer may overlap the pixel defining film.

In one or more embodiments, in the forming of the photoresist layer, a portion of the photoresist layer may overlap the sacrificial pattern.

One or more embodiments of the disclosure provide an electronic device for provide an image, the device including a display panel including a base layer, a pixel defining layer which is arranged on the base layer and in which a light emitting opening is defined, an auxiliary electrode which is arranged on the pixel defining layer and in which an auxiliary electrode opening overlapping the light emitting opening is defined, and a light emitting element including an anode arranged on the base layer and having at least a portion exposed by the light emitting opening, a cathode arranged on the auxiliary electrode and the anode, and a light emitting pattern arranged between the anode and the cathode and overlapping the light emitting opening, wherein the auxiliary electrode and the light emitting pattern are in direct contact with each other.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of a display device according to one or more embodiments of the disclosure;

FIG. 1B is an exploded perspective view of a display device according to one or more embodiments of the disclosure;

FIG. 2 is a cross-sectional view of a display module according to one or more embodiments of the disclosure;

FIG. 3 is a plan view of a display panel according to one or more embodiments of the disclosure;

FIGS. 4A and 4B are each an enlarged plan view of a portion of a display panel according to one or more embodiments of the disclosure;

FIG. 5 is a cross-sectional view of a display panel according to one or more embodiments of the disclosure;

FIG. 6 is a cross-sectional view of a display panel according to one or more embodiments of the disclosure;

FIG. 7 is a cross-sectional view of a display panel according to one or more embodiments of the disclosure;

FIG. 8 is a cross-sectional view of a display panel according to one or more embodiments of the disclosure; and

FIGS. 9A-9Q are cross-sectional views illustrating some of steps (or acts) of a method for manufacturing a display panel according to one or more embodiments of the disclosure.

### DETAILED DESCRIPTION

In this specification, it will be understood that if (e.g., when) an element (or region, layer, section, and/or the like) is referred to as being “on”, “connected to” or “coupled to” another element, it can be arranged directly on, connected or coupled to the other element or a third element may be arranged between the elements. In contrast, if an element (or region, layer, section, and/or the like.) is referred to as being “directly on”, “directly connected to” or “directly coupled to” another element, no intervening elements are present.

Like reference numbers or symbols refer to like elements throughout, and duplicative descriptions thereof may not be provided. In addition, in the drawings, the thickness, the ratio, and/or the dimension of elements are exaggerated for effective description of the technical contents. The term “and/or” includes one or more combinations which may be defined by relevant elements. Further, the use of “may” when describing embodiments of the present disclosure refers to “one or more embodiments of the present disclosure”.

It will be understood that, although the terms first, second, and/or the like may be used herein to describe various elements, these elements should not be limited by these terms. These terms are only used to distinguish one element from another element. For example, a first element could be termed a second element without departing from the teachings of the present disclosure, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

It will be further understood that the terms such as “comprises,” “includes” or “has”, if (e.g., when) used herein, specify the presence of stated features, numerals, steps, operations, elements, parts, or the combination thereof, but do not preclude the presence or addition of one or more other features, numerals, steps, operations, elements, parts, or the combination thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the disclosure will be described with reference to the accompanying drawings.

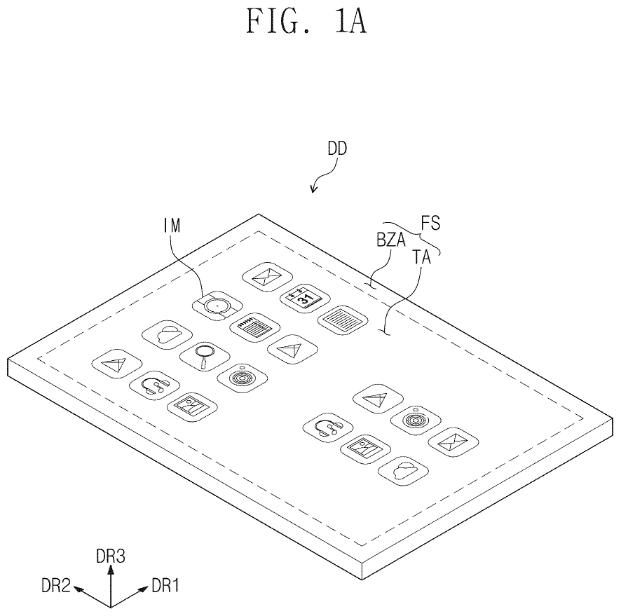

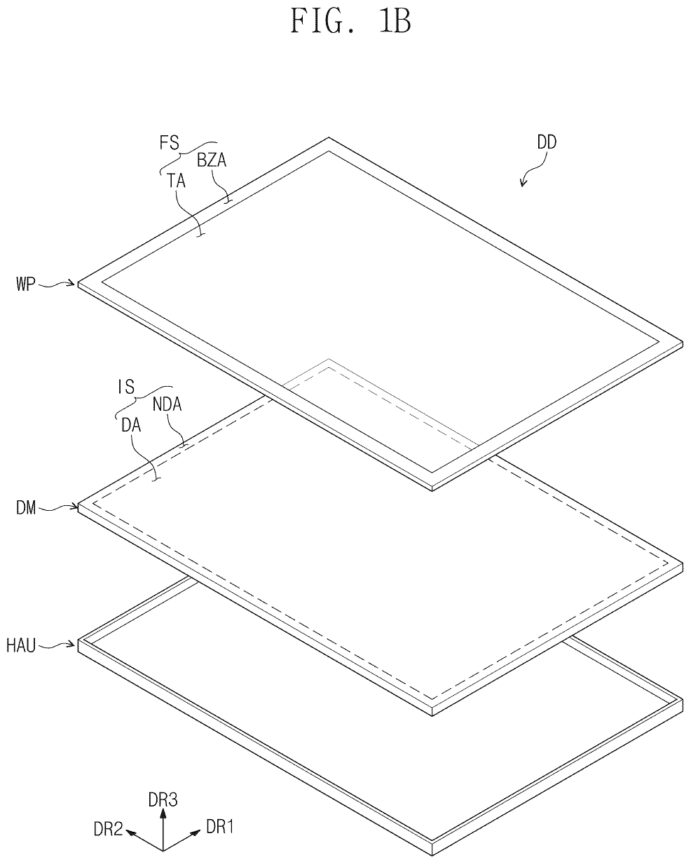

FIG. 1A is a perspective view of a display device DD according to one or more embodiments of the disclosure. FIG. 1B is an exploded perspective view of the display device DD according to one or more embodiments of the disclosure.

In one or more embodiments, the display device DD may be a large-sized electronic device such as a television, a monitor, and/or an outdoor billboard. In one or more embodiments, the display device DD may be a small- and/or a medium-sized electronic device such as a personal computer, a notebook computer, a personal digital assistant, a vehicle navigation unit, a game console, a smartphone, a tablet computer, and/or a camera. However, the foregoing devices are examples, and the display device DD may also be employed as other suitable display device without departing from the scope of the present disclosure. FIGS. 1A and 1B illustrate a tablet device as an example of the display device DD.

Referring to FIGS. 1A and 1B, the display device DD may display an image IM in a third direction DR3 on a display surface FS parallel to each of a first direction DR1 and a second direction DR2 (e.g., parallel to a plane defined by the first direction DR1 and the second direction DR2). The third direction DR3 may be a normal (e.g., substantially perpendicular) direction to the plane defined by the first direction DR1 and the second direction DR2. The image IM may include not only a dynamic image but also a still image. FIG. 1A illustrates a clock window and icons as an example of the image IM. The display surface FS on which the image IM is displayed may correspond to a front surface of the display device DD.

In this embodiment, a front surface (or top surface) and a rear surface (or bottom surface) of each member are defined based on a direction in which the image IM is displayed. The front surface and the rear surface may oppose each other in the third direction DR3, and a normal direction to each of the front surface and the rear surface may be parallel (or substantially parallel) to the third direction DR3. In one or more embodiments, directions indicated by the first to third directions DR1, DR2 and DR3 are relative concepts and may be changed to other directions. The term “on a plane” used herein may refer to a state “when viewed in the third direction DR3”.

The display device DD may include a window WP, a display module DM, and a housing HAU. The window WP and the housing HAU may be coupled to each other to constitute an outer appearance (e.g., outer shell) of the display device DD and may protect the display module DM.

The window WP may include an optically transparent insulation material. For example, the window WP may include glass and/or plastic. A front surface of the window WP may define the display surface FS of the display device DD. The display surface FS may include a transmission area TA and a bezel area BZA. The transmission area TA may be an optically transparent area. For example, the transmission area TA may be an area having a visible light transmittance of about 90% or more.

The bezel area BZA may be an area having a relatively low light transmittance when compared to the transmission area TA. The bezel area BZA may define a shape of the transmission area TA. The bezel area BZA may be adjacent to the transmission area TA and be around (e.g., surround) the transmission area TA. However, this is illustrated as an example, and the bezel area BZA of the window WP may be adjacent to only one side of the transmission area TA, or the bezel area BZA may not be provided in the window WP. In some embodiments, the window WP may include at least one functional layer selected from among an anti-fingerprint layer, a hard coating layer, and an anti-reflection layer, and is not limited to any one embodiment.

The display module DM may be arranged below the window WP. The display module DM may be a component that substantially generates the image IM. The image IM generated by the display module DM is displayed on a display surface IS of the display module DM, and is externally visible to a user through the transmission area TA.

The display module DM may include a display area DA and a non-display area NDA. The display area DA may be an area that is activated in response to an electrical signal. The non-display area NDA may be adjacent to the display area DA. The non-display area NDA may be around (e.g., surround) the display area DA. The non-display area NDA may be an area covered by the bezel area BZA, and may not be visible from the outside.

The housing HAU may be coupled to the window WP. As being coupled to the window WP, the housing HAU may provide a set or predetermined inner space. The display module DM may be accommodated in the inner space.

The housing HAU may include a material having relatively high (or suitably high) rigidity. For example, the housing HAU may include a plurality of frames and/or plates, each of which includes glass, plastic and/or metal, or is made of a combination thereof. The housing HAU may stably or suitably protect components of the display device DD accommodated in the inner space from external impact.

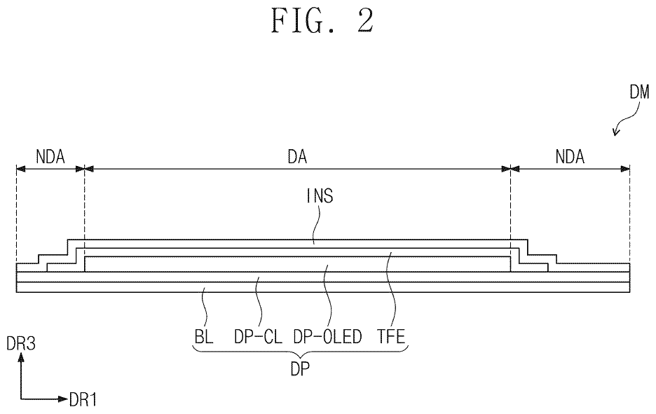

FIG. 2 is a cross-sectional view of a display module DM according to one or more embodiments of the disclosure.

Referring to FIG. 2, the display module DM may include a display panel DP and an input sensor INS. In some embodiments, the display device DD (see FIG. 1A) according to one or more embodiments of the disclosure may further include a protective member arranged on a bottom surface of the display panel DP, and/or an anti-reflection member and/or a window member that are arranged on a top surface of the input sensor INS.

The display panel DP may be an emissive display panel. For example, the display panel DP may be an organic light emitting display panel or an inorganic light emitting display panel. A light emitting layer in the organic light emitting display panel may include an organic light emitting material. A light emitting layer in the inorganic light emitting display panel may include a quantum dot, a quantum rod, and/or a micro LED. However, this is an illustrative example, and the display panel DP is not particularly limited thereto. Hereinafter, the display panel DP is described as the organic light emitting display panel.

The display panel DP may include a base layer BL, a circuit element layer DP-CL, a display element layer DP-OLED, and a thin-film encapsulation layer TFE that are arranged on the base layer BL. The input sensor INS may be arranged directly on the thin-film encapsulation layer TFE. In the present disclosure, “a component A being arranged directly on a component B” means that an adhesive layer is not arranged between the component A and the component B. However, this is illustrated as an example, and the input sensor may be attached to the display panel DP through a separate adhesive layer and/or the like, or may be provided in the form of being included inside the display panel DP. In one or more embodiments, the input sensor may not be provided, and is not limited to any one embodiment.

The base layer BL may be a base layer for providing the circuit element layer DP-CL, the display element layer DP-OLED, and the thin-film encapsulation layer TFE thereon. The base layer BL may have insulating properties. For example, the base layer BL may include at least one plastic film. The base layer BL may be a flexible substrate and may include a plastic substrate, a glass substrate, a metal substrate, an organic/inorganic composite material substrate, and/or the like. A display area DA and a non-display area NDA that are the same as/similar to those described with reference to FIG. 1B may be defined (e.g., provided) on the base layer BL.

The circuit element layer DP-CL may be arranged on the base layer BL. The circuit element layer DP-CL may include at least one circuit element and an insulation layer. The insulation layer may include at least one inorganic layer and at least one organic layer. The circuit element may include signal lines, a driving circuit of a pixel, and/or the like.

The display element layer DP-OLED may be arranged on the circuit element layer DP-CL. The display element layer DP-OLED may include a light emitting element ED. The light emitting element ED may include an anode, an intermediate layer, and a cathode.

The thin-film encapsulation layer TFE may include a plurality of thin films. The thin films may include an inorganic layer and/or an organic layer, and each of the inorganic layer and the organic layer may have a single-layer structure or a multilayer structure. The thin-film encapsulation layer TFE may protect the light emitting element ED and/or may improve luminous efficiency of the light emitting element ED.

The input sensor INS may be arranged on the display panel DP. The input sensor INS obtains coordinate information of an external input. The input sensor INS may include a conductive layer having a single-layer structure or a multilayer structure. In one or more embodiments, the input sensor INS may include an insulation layer having a single-layer structure or a multilayer structure. The input sensor INS may detect an external input by using a capacitance method. However, this is an illustrative example, and one or more embodiments of the disclosure are not limited thereto. For example, in one or more embodiments, the input sensor INS may detect an external input by using an electromagnetic induction method and/or a pressure detection method. In one or more embodiments, the input sensor INS may not be provided.

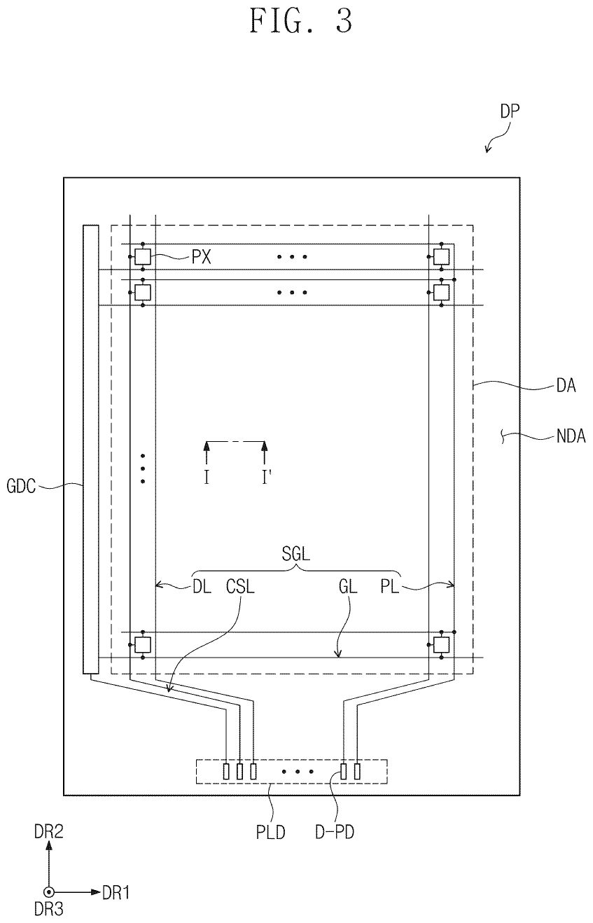

FIG. 3 is a plan view of a display panel according to one or more embodiments of the disclosure. FIG. 3 is a schematic view illustrating some components of a display panel DP for ease of explanation.

Referring to FIG. 3, the display panel DP may include pixels PX, signal lines SGL, a driving circuit GDC, and a pad part PLD. The display panel DP may include the pixels PX, and the signal lines SGL, the driving circuit GDC, and the pad part PLD that are electrically connected to the pixels PX.

The pixels PX may be arranged on a display area DA. The pixels PX may be arranged in the first direction DR1 and the second direction DR2. The pixels PX may include a plurality of pixel rows, which extend in the first direction DR1 and are arranged in the second direction DR2, and a plurality of pixel columns which extend in the second direction DR2 and are arranged in the first direction DR1.

Each of the pixels PX may include a light emitting element and a pixel circuit that drives the light emitting element. The light emitting element may include an organic light emitting diode, and the pixel circuit may include at least one transistor connected (e.g., electrically connected) to the light emitting element, and a capacitor.

The signal lines SGL may include gate lines GL, data lines DL, a power line PL, and a control signal line CSL. Each of the gate lines GL may be connected (e.g., electrically connected) to a corresponding pixel PX of the pixels PX, and each of the data lines DL may be connected (e.g., electrically connected) to a corresponding pixel PX of the pixels PX. The power line PL may be electrically connected to the pixels PX. The control signal line CSL may be connected (e.g., electrically connected) to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to a pixel driving circuit.

The pad part PLD may be a portion to which a circuit board is connected (e.g., physically and/or electrically connected). The pad part PLD may include pixel pads D-PD, and the pixel pads D-PD may be pads for connecting a flexible circuit board to the display panel DP. Each of the pixel pads D-PD may be connected to a corresponding signal line of the signal lines SGL. One of the pixel pads D-PD may be connected to the control signal line CSL to transmit a control signal to the driving circuit GDC. Some of the pixel pads D-PD may be connected to the data lines DL to transmit data signals to the pixels PX, respectively.

The pad part PLD may further include input pads. The input pads may be pads for connecting the circuit board to the input sensor INS (see FIG. 2). However, one or more embodiments of the present disclosure are not limited thereto, and the input pads may be arranged on the input sensor INS (see FIG. 2) and connected to a separate circuit board from the pixel pads D-PD. In one or more embodiments, the input sensor INS (see FIG. 2) may not be provided, and may not further include the input pads.

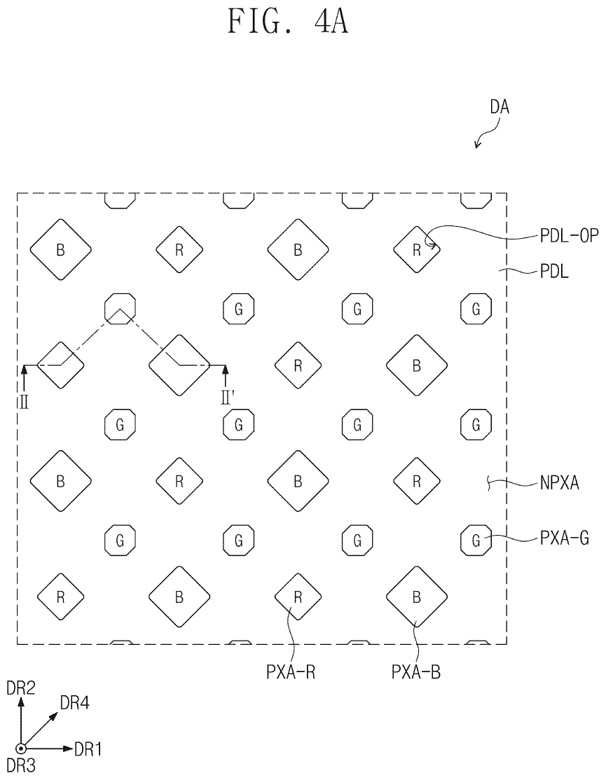

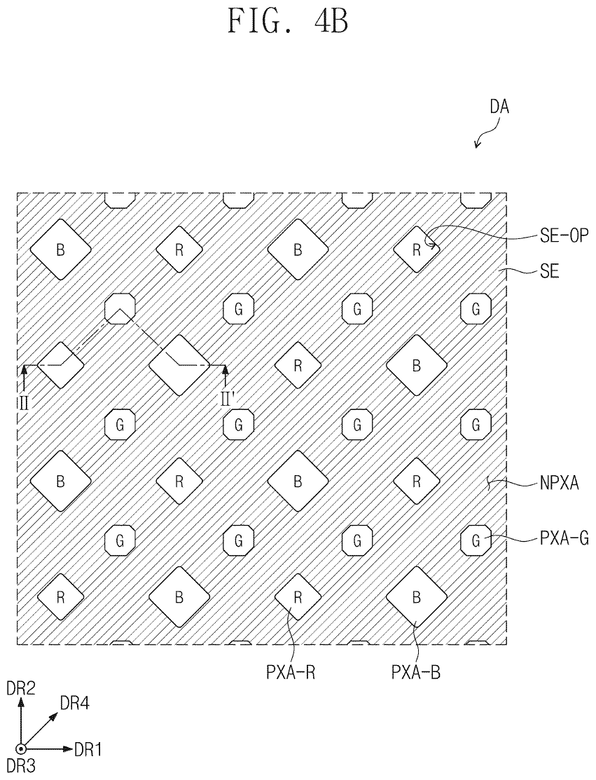

FIGS. 4A and 4B are enlarged plan views of a portion of a display panel according to one or more embodiments of the disclosure. FIGS. 4A and 4B are each an enlarged view illustrating a portion of a display area DA of the display panel DP (see FIG. 2). FIG. 4A illustrates a plane of a pixel defining layer PDL to be described in more detail hereinbelow when viewed on the display surface IS (see FIG. 1B) of the display module DM (see FIG. 1B), and FIG. 4B illustrates a plane of an auxiliary electrode SE when viewed on the display surface IS (see FIG. 1B) of the display module DM (see FIG. 1B).

Referring to FIGS. 4A and 4B, the display area DA may include first to third light emitting areas PXA-R, PXA-G and PXA-B and a peripheral area NPXA. The peripheral area NPXA may be an area around (e.g., surrounding) the first to third light emitting areas PXA-R, PXA-G and PXA-B. The first to third light emitting areas PXA-R, PXA-G and PXA-B may correspond respectively to areas from which light provided from light emitting elements is (or is configured to be) emitted.

The first to third light emitting areas PXA-R, PXA-G and PXA-B may provide light having first to third colors different from each other, respectively. For example, the light having the first color may be red light, the light having the second color may be green light, and the light having the third color may be blue light. However, examples of the light having the first to third colors are not necessarily limited to the foregoing examples.

The peripheral area NPXA may set a boundary between the first to third light emitting areas PXA-R, PXA-G and PXA-B, and may prevent or reduce color mixture between the first to third light emitting areas PXA-R, PXA-G and PXA-B.

The first to third light emitting areas PXA-R, PXA-G and PXA-B may be each provided in plurality, and be repeatedly arranged to have a set or predetermined arrangement shape in the display area DA. For example, the first and third light emitting areas PXA-R and PXA-B may be arranged alternately with each other in the first direction DR1 to constitute a “first group”. The second light emitting areas PXA-G may be arranged in the first direction DR1 to constitute a “second group”. Each of the “first group” and the “second group” may be provided in plurality, and the “first groups” and the “second groups” may be arranged to alternate with each other in the second direction DR2.

One second light emitting area PXA-G may be arranged to be spaced and/or apart (e.g., spaced apart or separated) from one first light emitting area PXA-R and/or one third light emitting area PXA-B in a fourth direction DR4. The fourth direction DR4 may be defined as a direction between the first and second directions DR1 and DR2 (e.g., a diagonal direction).

FIGS. 4A and 4B each illustrate an example of the arrangement shape of the first to third light emitting areas PXA-R, PXA-G and PXA-B. However, one or more embodiments of the present disclosure are not limited thereto, and the first to third light emitting areas PXA-R, PXA-G and PXA-B may be arranged in one or more suitable shapes. In one or more embodiments, the first to third light emitting areas PXA-R, PXA-G and PXA-B may have a PENTILE® arrangement shape as illustrated in FIGS. 4A and 4B (PENTILE® is a registered trademark owned by Samsung Display Co., Ltd.). In one or more embodiments, the first to third light emitting areas PXA-R, PXA-G and PXA-B may have a stripe arrangement shape or a diamond (Diamond Pixel®, a registered trademark owned by Samsung Display Co., Ltd.) arrangement shape.

The first to third light emitting areas PXA-R, PXA-G and PXA-B may have one or more suitable shapes when viewed on a plane. For example, each of the first to third light emitting areas PXA-R, PXA-G and PXA-B may have a shape such as a polygonal, circular, and/or oval shape. As an example, FIGS. 4A and 4B illustrate the first and third light emitting areas PXA-R and PXA-B each having a rectangular (or rhombus) shape on a plane, and the second light emitting areas PXA-G each having an octagonal shape on a plane.

The first to third light emitting areas PXA-R, PXA-G and PXA-B may have the same shape on a plane, or in some embodiments, at least some of the first to third light emitting areas PXA-R, PXA-G and PXA-B may have different shapes on a plane. As an example, FIGS. 4A and 4B illustrate the first and third light emitting areas PXA-R and PXA-B having the same shape on a plane, and the second light emitting area PXA-G having a different shape from the first and third light emitting areas PXA-R and PXA-B on a plane.

At least some of the first to third light emitting areas PXA-R, PXA-G and PXA-B may have different surface areas on a plane. In one or more embodiments, a surface area of the first light emitting area PXA-R that is to emit the red light may be greater than a surface area of the second light emitting area PXA-G that is to emit the green light, and be less than a surface area of the third light emitting area PXA-B that is to emit the blue light. However, a size (large-small) relationship between the surface areas of the first to third light emitting areas PXA-R, PXA-G and PXA-B according to the colors of the emitted light is not limited thereto, and may vary according to the design of the display module DM (see FIG. 2). Embodiments of the disclosure are not limited thereto, and the first to third light emitting areas PXA-R, PXA-G and PXA-B may have the same surface area on a plane.

The shape, surface area, arrangement, and/or the like of the first to third light emitting areas PXA-R, PXA-G and PXA-B of the display module DM (see FIG. 2) according to one or more embodiments of the disclosure may be variously suitably designed according to the color of the emitted light, the size, and/or configuration of the display module DM (see FIG. 2), and are not limited to the one or more embodiments illustrated in FIGS. 4A and 4B.

Referring to FIG. 4A, a light emitting opening PDL-OP may be defined in the pixel defining layer PDL. The light emitting opening may correspond to each of the light emitting areas. Each of the light emitting areas may be substantially defined by the light emitting opening. This will be described in more detail herein below.

Referring to FIG. 4B, an auxiliary electrode opening SE-OP may be defined in the auxiliary electrode SE. The auxiliary electrode opening may correspond to the light emitting opening. For example, the auxiliary electrode opening may have a similar shape to the light emitting opening when viewed on a plane. The auxiliary electrode opening may have a surface area similar to or substantially the same as a surface area of the light emitting opening.

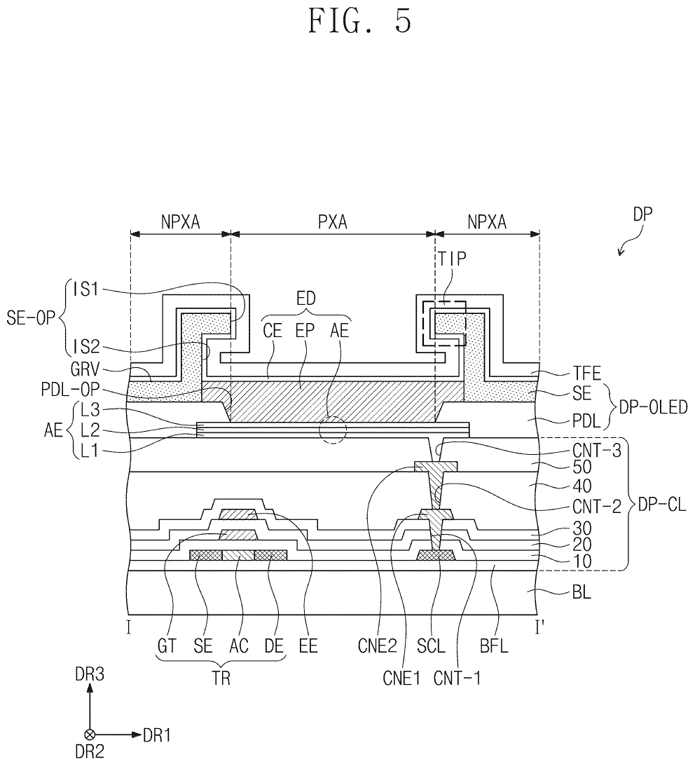

FIG. 5 is a cross-sectional view of a display panel DP according to one or more embodiments of the present disclosure.

The display panel DP may include a base layer BL, a circuit element layer DP-CL, and a display element layer DP-OLED.

The display panel DP may include a plurality of insulation layers, a semiconductor pattern, a conductive pattern, a signal line, and/or the like. First, the insulation layers, a semiconductor layer, and a conductive layer are formed through coating, deposition, and/or the like. Thereafter, the insulation layers, the semiconductor layer, and the conductive layer may be selectively patterned through a photolithography process and an etching process. The semiconductor pattern, the conductive pattern, and the signal line, and/or the like, which are included in the circuit element layer DP-CL and the display element layer DP-OLED, may be formed through those processes.

The circuit element layer DP-CL may be arranged on the base layer BL. The circuit element layer DP-CL may include a buffer layer BFL, a transistor TR, a signal transmission line SCL, first to fifth insulation layers 10, 20, 30, 40 and 50, an upper electrode EE, and a plurality of connection electrodes CNE1 and CNE2. For ease of explanation, FIG. 5 illustrates the transistor TR, the signal transmission line SCL, and the plurality of connection electrodes CNE1 and CNE2 among driving elements, and illustrates the first to fifth insulation layers 10, 20, 30, 40 and 50 stacked in sequence. However, this is illustrated as an example, and a configuration and an arrangement relationship of the driving elements constituting the circuit element layer DP-CL may be variously suitably changed, and is not limited to any one embodiment.

The buffer layer BFL may be arranged on the base layer BL. The buffer layer BFL may improve a bonding force between the base layer BL and the semiconductor pattern. The buffer layer BFL may include a silicon oxide layer and/or a silicon nitride layer. In a case in which the buffer layer BFL includes the silicon oxide layer and the silicon nitride layer, the two layers may be alternately stacked.

The transistor, the plurality of connection electrodes, and the first to fifth insulation layers may be arranged on the buffer layer BFL. The first to fifth insulation layers 10, 20, 30, 40 and 50 may be arranged on the buffer layer BFL. Each of the first to fifth insulation layers 10, 20, 30, 40 and 50 may be an inorganic layer and/or an organic layer.

The first insulation layer 10 may be arranged on the buffer layer BFL. The first insulation layer 10 may cover a source SE, an active AC, and a drain DE of the transistor TR, and the signal transmission line SCL which are arranged on the buffer layer BFL. A gate GT of the transistor TR may be arranged on the first insulation layer 10. The second insulation layer 20 may be arranged on the first insulation layer 10 and cover the gate GT. The upper electrode EE may be arranged on the second insulation layer 20. The third insulation layer 30 may be arranged on the second insulation layer 20 and cover the upper electrode EE.

The transistor TR may include a semiconductor pattern and a gate electrode GT.

The semiconductor pattern may be arranged on the buffer layer BFL. The semiconductor pattern may include polysilicon. However, one or more embodiments of the disclosure are not limited thereto, and the semiconductor pattern may include amorphous silicon and/or a metal oxide. FIG. 5 illustrates a portion of the semiconductor pattern as an example, and at least one semiconductor pattern may be further arranged in the plurality of light emitting areas PXA-R, PXA-G and PXA-B (see FIG. 4). The semiconductor pattern may include a plurality of regions divided according to conductivity.

The semiconductor pattern may include the source region SE, the active region AC, and the drain region DE. The active region AC may be a region having relatively low electrical conductivity compared to the source region SE and the drain region DE. The source region SE and the drain region DE may be arranged to be spaced and/or apart (e.g., spaced apart or separated) from each other with the active region AC therebetween.

The gate electrode GT may be arranged between the first insulation layer 10 and the second insulation layer 20. The gate electrode GT may overlap the active region AC of the semiconductor pattern. In this embodiment, a transistor with a top-gate structure is illustrated as an example of the transistor TR. However, this is illustrated as an example, and the gate electrode GT may be arranged below the semiconductor pattern and is not limited to any one embodiment.

The signal transmission line SCL may have conductivity. In this embodiment, the signal transmission line SCL is arranged on the same layer as the semiconductor pattern. In some embodiments, the signal transmission line SCL may be formed at the same time (e.g., concurrently) as the semiconductor pattern. For example, the signal transmission line SCL may be provided by forming a region having high (or suitable) conductivity in the semiconductor pattern through a doping process and/or the like. As the signal transmission line SCL and the semiconductor pattern of the transistor TR are formed at the same time (e.g., concurrently), the process may be simplified, and process costs may be reduced. However, this is described as an example. The signal transmission line SCL may be formed by patterning a conductive material such as a metal unlike (e.g., different from) the semiconductor pattern, and/or may be formed on a different layer from the semiconductor pattern, and is not limited to any one embodiment.

In one or more embodiments, the circuit element layer DP-CL may further include the upper electrode EE. The upper electrode EE is arranged between the second insulation layer 20 and the third insulation layer 30. The second insulation layer 20 may be a layer that covers the transistor TR.

The upper electrode EE may at least partially overlap the gate electrode GT. The upper electrode EE may provide a capacitor together with the gate electrode GT. The capacitor may be a storage capacitor constituting a pixel circuit. According to one or more embodiments of the disclosure, as the upper electrode EE is further included, the capacitor and the transistor TR may be arranged to overlap each other on a plane. Accordingly, an integration level of the pixel circuit may be improved, and a high-resolution display panel may be easily or suitably designed. However, this is illustrated as an example, and the capacitor may be provided at a position not overlapping the transistor TR, and/or the upper electrode EE and the gate electrode GT may not provide the capacitor. In one or more embodiments, the upper electrode EE may not be provided and is not limited to any one embodiment.

A first connection electrode CNE1 may be arranged between the third insulation layer 30 and the fourth insulation layer 40. The third insulation layer 30 covers the upper electrode EE. The third insulation layer 30 may be an inorganic layer, and the fourth insulation layer 40 may be an organic layer. However, one or more embodiments of the disclosure are not limited thereto. The first connection electrode CNE1 may pass through the first, second and third insulation layers 10, 20 and 30 and be connected to the signal transmission line SCL through a connection contact hole CNT-1.

A second connection electrode CNE2 may be arranged between the fourth insulation layer 40 and the fifth insulation layer 50. The second connection electrode CNE2 may pass through the fourth and fifth insulation layers 40 and 50 via a connection contact hole CNT-2 and be electrically connected to the signal transmission line SCL (e.g., through the first connection electrode CNE1). A signal flowing through the signal transmission line SCL may be transmitted to the display element layer DP-OLED through the first connection electrode CNE1 and the second connection electrode CNE2.

The display element layer DP-OLED may be arranged on the circuit element layer DP-CL. The display element layer DP-OLED may include a pixel defining layer PDL, an auxiliary electrode SE, and a light emitting element ED.

The pixel defining layer PDL may be arranged on the fifth insulation layer 50 of the circuit element layer DP-CL. A light emitting opening PDL-OP may be defined (or provided) in the pixel defining layer PDL. The light emitting opening PDL-OP may correspond to an anode AE, and the pixel defining layer PDL may expose at least a portion of the anode AE through the light emitting opening PDL-OP.

The pixel defining layer PDL may include an inorganic insulation material. For example, the pixel defining layer PDL may include a silicon nitride (SiNₓ, where 0<x≤2, for example, Si₃N₄).

The light emitting element ED may include the anode AE (or first electrode), a light emitting pattern EP, and a cathode CE (or second electrode).

The anode AE may be arranged on the fifth insulation layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 passing through and defined in the fifth insulation layer 50. Thus, the anode AE may be electrically connected to the signal transmission line SCL through the first and second connection electrodes CNE1 and CNE2, and be electrically connected to a corresponding circuit element. The anode AE may have a single-layer structure or a multilayer structure. The anode AE may include a plurality of layers including ITO and/or Ag. For example, the anode AE may include a layer L1 including ITO (hereinafter referred to as a lower ITO layer), a layer L2 arranged on the lower ITO layer and including Ag (hereinafter referred to as an Ag layer), and a layer L3 arranged on the Ag layer and including ITO (hereinafter referred to as an upper ITO layer). However, one or more embodiments of the disclosure are not limited thereto, and the anode AE may be provided as a single layer.

The light emitting pattern EP may be arranged on the anode AE. The light emitting pattern EP may include a light emitting layer including a light emitting material. The light emitting pattern EP may further include a hole injection layer HIL and a hole transport layer HTL, which are arranged between the anode AE and the light emitting layer, and may further include an electron transport layer ETL and an electron injection layer EIL, which are arranged on the light emitting layer. The light emitting pattern EP may be referred to as an “organic layer” and/or an “intermediate layer”.

The light emitting pattern EP may be arranged inside the light emitting opening PDL-OP and an auxiliary electrode opening SE-OP to be described in more detail herein below. However, this is illustrated as an example, and one or more embodiments of the disclosure are not limited thereto. The light emitting pattern EP may cover a portion of a top surface of the pixel defining layer PDL.

The cathode CE may be arranged on the light emitting pattern EP. At least a portion of the cathode CE may be arranged in the auxiliary electrode opening SE-OP. As an example, FIG. 5 illustrates the cathode CE being arranged in the light emitting opening PDL-OP and the auxiliary electrode opening SE-OP, but one or more embodiments of the disclosure are not limited thereto. For example, the cathode CE may be arranged only in the auxiliary electrode opening SE-OP.

The cathode CE may entirely cover a top surface of the auxiliary electrode SE. For example, the cathode CE may cover all of a first surface IS1 of the auxiliary electrode opening SE-OP, a second surface IS2 of the auxiliary electrode opening SE-OP, and a bottom surface of a tip TIP defined on the auxiliary electrode SE.

The cathode CE may have conductivity. The cathode CE may be made of one or more suitable materials such as a metal, a transparent conductive oxide (TCO), and/or a conductive polymeric material, as long as the cathode is capable of having conductivity. For example, the cathode CE may include silver (Ag), magnesium (Mg), lead (Pb), copper (Cu), or a compound thereof.

The auxiliary electrode SE may be arranged on the pixel defining layer PDL. The auxiliary electrode SE may be in direct contact with the light emitting pattern EP. For example, the auxiliary electrode SE may be in direct contact with both (e.g., opposite) side surfaces of the light emitting pattern EP. In the present context, “in direct contact” refers to that the auxiliary electrode SE is physically touching the light-emitting pattern EP without any intervening material. Specifically, the auxiliary electrode SE is in direct contact with both side surfaces of the light-emitting pattern EP, ensuring there is no gap or layer between them.

A groove GRV overlapping a peripheral region NPXA may be defined in a top surface of the auxiliary electrode SE. The groove GRV may be a portion which is defined in the top surface of the auxiliary electrode SE and recessed toward the pixel defining layer PDL. The groove GRV may be provided to overlap the pixel defining layer PDL on a plane.

The auxiliary electrode opening SE-OP overlapping the light emitting opening PDL-OP may be defined in the auxiliary electrode SE. The auxiliary electrode opening SE-OP may be defined by an inner side surface of the auxiliary electrode SE. The inner side surface may have a stepped portion when viewed in a cross-section. For example, an inner side surface of the auxiliary electrode opening SE-OP may be divided into the first surface IS1 and the second surface IS2 which provide (e.g., form) the stepped portion. The first surface IS1 may be spaced farther apart from the pixel defining layer PDL than the second surface IS2 in the third direction DR3. The second surface IS2 may be spaced apart from the light emitting pattern EP in a cross-section (e.g., may not overlap the light emitting pattern EP in the first direction DR1).

The second surface IS2 may be arranged closer to the pixel defining layer PDL than the first surface IS1 (e.g., along the third direction DR3). The second surface IS2 may be arranged below the first surface IS1. At least a portion of the second surface IS2 may be in contact with the light emitting pattern EP. A width of the auxiliary electrode opening SE-OP defined by the first surface IS1 may be different from a width of the auxiliary electrode opening SE-OP defined by the second surface IS2. The width of the auxiliary electrode opening SE-OP defined by the second surface IS2 may be greater than the width of the auxiliary electrode opening SE-OP defined by the first surface IS1.

The tip TIP may be defined in the auxiliary electrode opening SE-OP. For example, the first surface IS1 may define the tip TIP protruding from the second surface IS2 toward a center of the auxiliary electrode opening SE-OP. The tip TIP may overlap the light emitting pattern EP on a plane, and may be spaced and/or apart (e.g., spaced apart or separated) from the light emitting pattern EP in a cross-section (e.g., along the third direction DR3).

The auxiliary electrode SE may have a larger thickness than the cathode CE. The auxiliary electrode SE may also have higher conductivity than at least the cathode CE. The auxiliary electrode SE may include a conductive material. For example, the conductive material may include a metal, a transparent conductive oxide (TCO), and/or a (e.g., any suitable) combination thereof. For example, the metal may include gold (Au), silver (Ag), aluminum (Al), magnesium (Mg), lithium (Li), molybdenum (Mo), titanium (Ti), copper (Cu), and/or an alloy. The transparent conductive oxide may include an indium tin oxide (ITO), an indium zinc oxide (IZO), a zinc oxide, an indium oxide, an indium gallium oxide, an indium gallium zinc oxide (IGZO), and/or an aluminum zinc oxide.

The auxiliary electrode SE may be in direct contact with the cathode CE, and the auxiliary electrode SE and the cathode CE may be electrically connected to each other. The auxiliary electrode SE may be arranged in the peripheral area NPXA and thus may be provided with any suitable thickness. The resistance of the cathode CE of the display panel DP may be decreased through this auxiliary electrode SE, thereby reducing or preventing unevenness in luminance that is likely to occur as a surface area of the display area DA increases. In addition, as the auxiliary electrode SE and the cathode CE are brought into contact with each other when the cathode CE is formed, a separate connection process such as laser drilling and/or contact hole forming process may not be provided. Thus, the process may be simplified, and the process costs may be reduced. In the present context, “in direct contact” refers to that the auxiliary electrode SE is physically touching the cathode CE without any intervening material. This direct contact ensures that the auxiliary electrode SE and the cathode CE are electrically connected.

The display element layer DP-OLED may further include an inorganic encapsulation film TFE. As an example, FIG. 5 illustrates the display element layer DP-OLED including the inorganic encapsulation film TFE. However, one or more embodiments are not limited thereto, and the inorganic encapsulation film TFE may not be provided.

The inorganic encapsulation film TFE may be arranged on the display element layer DP-OLED. The inorganic encapsulation film TFE may protect the display element layer DP-OLED from moisture, oxygen, and/or foreign matter such as dust particles. The inorganic encapsulation film TFE may have a single-layer structure, or have a multilayer structure in which layers are stacked in the third direction DR3. For example, the inorganic encapsulation film TFE may include a single-layer inorganic film, or have a structure in which multilayer inorganic films are stacked. The inorganic encapsulation film TFE may protect the display element layer DP-OLED from moisture and/or oxygen. The inorganic encapsulation film TFE may include a silicon nitride layer, a silicon oxynitride layer, a silicon oxide layer, a titanium oxide layer, an aluminum oxide layer, and/or the like.

The inorganic encapsulation film TFE may cover the groove GRV defined in the auxiliary electrode SE. The inorganic encapsulation film TFE may cover a top surface of the tip TIP, the first surface IS1 of the auxiliary electrode opening SE-OP, and the second surface IS2 of the auxiliary electrode opening SE-OP.

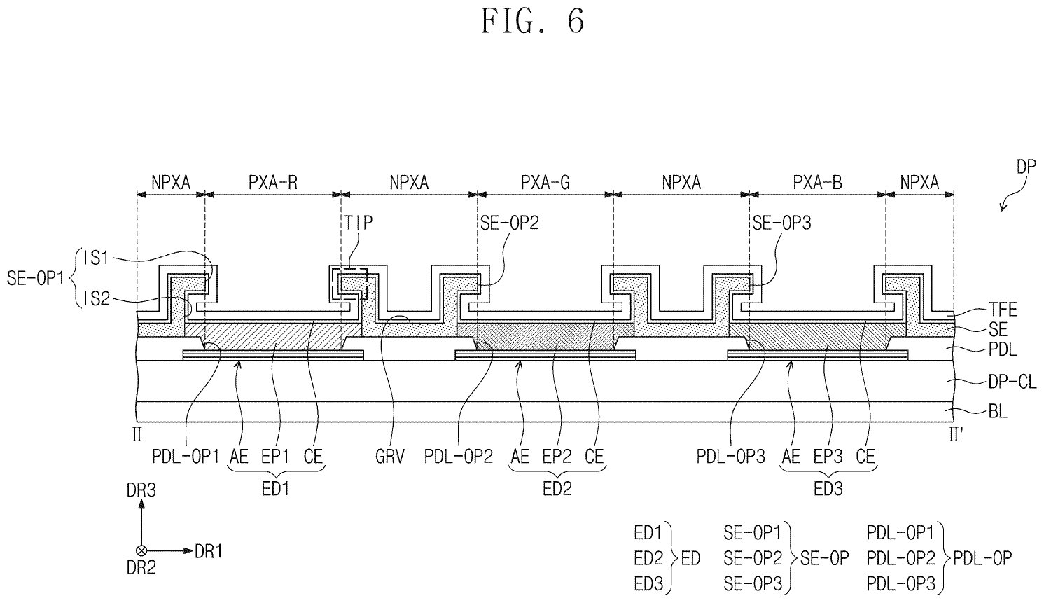

FIG. 6 is a cross-sectional view of a display panel DP according to one or more embodiments of the disclosure. Hereinafter, one or more embodiments will be described with reference to FIG. 6 by denoting the same/similar components as/to those described with reference to FIG. 5 as the same/similar reference numbers or symbols, and avoiding redundant contents.

Referring to FIG. 6, a first light emitting element ED1, a second light emitting element ED2, and a third light emitting element ED3 may be arranged in first to third light emitting openings PDL-OP1, PDL-OP2 and PDL-OP3, respectively. As an example, the first to third light emitting elements ED1, ED2 and ED3 are illustrated as emitting (or configured to emit) light having different colors, and thus first to third light emitting areas PXA-R, PXA-G and PXA-B may be areas in which different light is displayed.

An auxiliary electrode opening SE-OP may include first to third auxiliary electrode openings SE-OP1, SE-OP2 and SE-OP3 overlapping the first to third light emitting openings PDL-OP1, PDL-OP2 and PDL-OP3, respectively.

Referring to FIG. 6, an auxiliary electrode SE may include a groove GRV overlapping a peripheral area NPXA. The groove GRV may be a portion which is defined in a top surface of the auxiliary electrode SE and recessed toward a pixel defining layer PDL. The groove GRV may be provided to overlap the pixel defining layer PDL (e.g., along the third direction DR3). For example, an auxiliary electrode SE features a groove GRV overlapping a peripheral area NPXA. This groove GRV is recessed toward a pixel defining layer PDL and overlaps it along a specified direction DR3.

The auxiliary electrode SE may include a tip TIP protruding toward each of the first to third light emitting areas PXA-R, PXA-G and PXA-B. As described above, the tip TIP may be a portion defined by an inner side surface of the auxiliary electrode SE and protruding toward a center of each of the first to third light emitting areas PXA-R, PXA-G and PXA-B.

As an example, FIG. 6 illustrates the auxiliary electrode SE being arranged in each of an area between the first light emitting area PXA-R and the second light emitting area PXA-G and an area between the second light emitting area PXA-G and the third light emitting area PXA-B. However, one or more embodiments of the disclosure are not limited thereto, and the auxiliary electrode SE may be arranged only in the area between the first light emitting area PXA-R and the second light emitting area PXA-G, or be arranged only in the area between the second light emitting area PXA-G and the third light emitting area PXA-B.

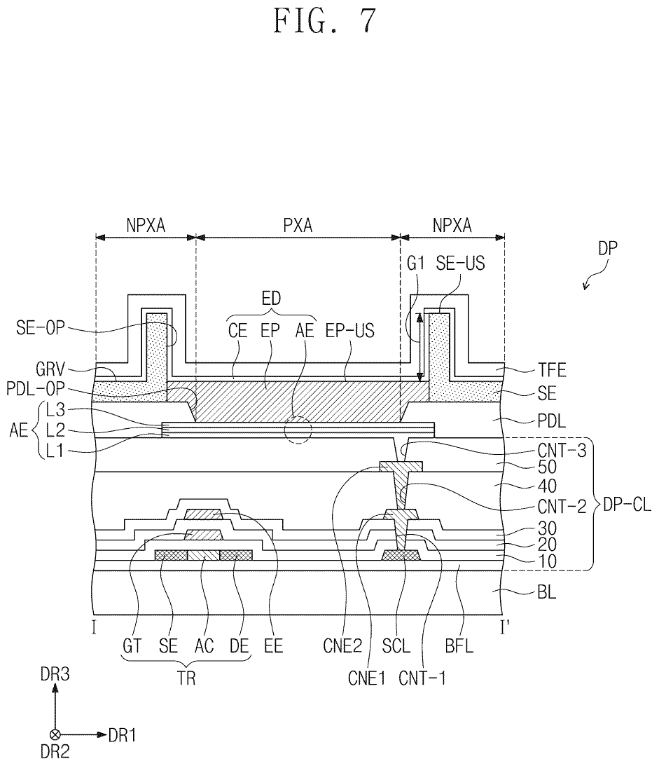

FIG. 7 is a cross-sectional view of a display panel DP according to one or more embodiments of the disclosure. Hereinafter, one or more embodiments will be described with reference to FIG. 7 by denoting the same/similar components as/to those described with reference to FIGS. 5 and 6 as the same/similar reference numbers or symbols, and avoiding redundant contents.

Referring to FIG. 7, an auxiliary electrode opening SE-OP may have a shape having a substantially uniform width in a cross-section. For example, the auxiliary electrode opening SE-OP may have a shape in which the tip TIP and/or the stepped portion illustrated in FIG. 5 is removed (is not provided). Here, an inner side surface of the auxiliary electrode opening SE-OP may be provided as one substantially linear (or flat) surface with no stepped portion. The inner side surface of the auxiliary electrode opening SE-OP may be substantially aligned with a side surface of a light emitting pattern EP in a cross-section.

The inner side surface of the auxiliary electrode opening SE-OP may include a portion that is not in contact with the light emitting pattern EP. For example, the inner side surface may include a portion in contact with the light emitting pattern EP, and a portion exposed from (e.g., extending above) the light emitting pattern EP.

Referring to FIG. 7, an auxiliary electrode SE may include a groove GRV overlapping a peripheral area NPXA. The groove GRV may be a portion which is defined in a top surface of the auxiliary electrode SE and recessed toward a pixel defining layer PDL. The groove GRV may be provided to overlap the pixel defining layer PDL. The groove GRV may overlap the pixel defining layer PDL but not overlap a light emitting opening PDL-OP defined in the pixel defining layer PDL (e.g., along the third direction DR3). For example, an auxiliary electrode SE includes a groove GRV that overlaps a peripheral area NPXA. This groove GRV is recessed toward and overlaps the pixel defining layer PDL but does not overlap the light-emitting opening PDL-OP within the pixel defining layer PDL, along the third direction DR3.

A top surface SE-US of the auxiliary electrode SE may be spaced a fixed distance G1 from a top surface EP-US the light emitting pattern EP. The top surface SE-US of the auxiliary electrode SE may protrude from the top surface EP-US the light emitting pattern EP.

A cathode CE may entirely cover the top surface SE-US of the auxiliary electrode SE and the top surface EP-US the light emitting pattern EP. Here, as a region to which the auxiliary electrode SE and the light emitting pattern EP are adjacent has a stepped portion (e.g., due to the inner side surface of the auxiliary electrode opening SE-OP which is not in contact with the light emitting pattern EP and/or the region in which the groove GRV is formed), the cathode CE may also include a stepped portion likewise.

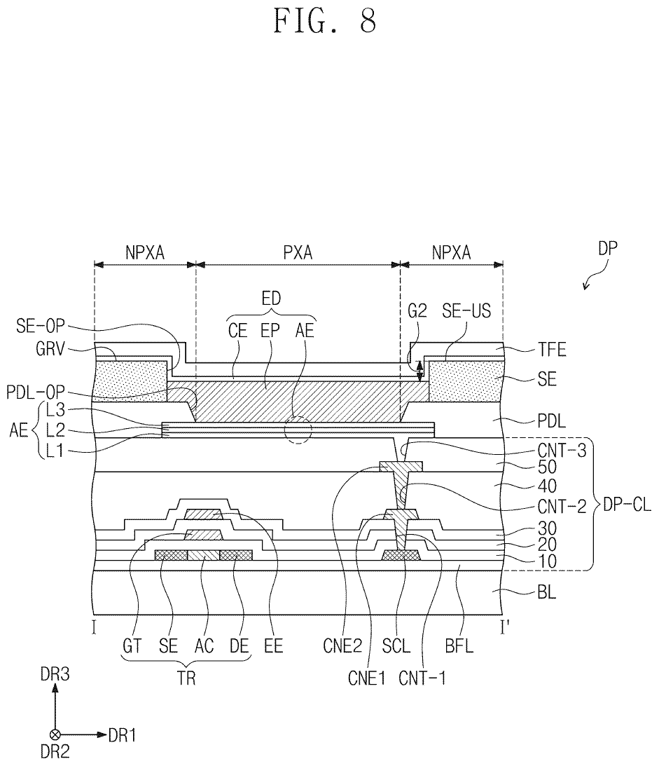

FIG. 8 is a cross-sectional view of a display panel DP according to one or more embodiments of the disclosure. Hereinafter, one or more embodiments will be described with reference to FIG. 8 by denoting the same/similar components as/to those described with reference to FIGS. 5 and 6 as the same/similar reference numbers or symbols, and avoiding redundant contents.

Referring to FIG. 8, an auxiliary electrode opening SE-OP may have a shape having a substantially uniform width in a cross-section. For example, the auxiliary electrode opening SE-OP may have a shape in which the tip TIP and/or the stepped portion illustrated in FIG. 5 is removed (are not provided). Here, an inner side surface of the auxiliary electrode opening SE-OP may be provided as one substantially linear (or flat) surface with no stepped portion. The inner side surface of the auxiliary electrode opening SE-OP may be substantially aligned with a side surface of a light emitting pattern EP on a cross-section.

The inner side surface of the auxiliary electrode opening SE-OP may include a portion that is not in contact with the light emitting pattern EP. For example, the inner side surface may include a portion in contact with the light emitting pattern EP, and a portion exposed from (e.g., extending above) the light emitting pattern EP.

Referring to FIG. 8, a top surface SE-US of an auxiliary electrode SE may be a substantially flat surface. For example, the top surface SE-US of the auxiliary electrode SE may be in a substantially straight line shape extending in the first direction DR1 and/or the second direction DR2 on a cross-section, and may have a shape with no groove GRV and/or the like described above, or may have a groove GRV that is not recessed. The top surface SE-US of the auxiliary electrode SE may not have a stepped portion.

The top surface SE-US of the auxiliary electrode SE may be spaced a fixed distance G2 from a top surface EP-US the light emitting pattern EP. The top surface SE-US of the auxiliary electrode SE may protrude from the top surface EP-US the light emitting pattern EP. The inner side surface of the auxiliary electrode opening SE-OP may include a portion that is not in contact with the light emitting pattern EP. For example, a region to which the auxiliary electrode SE and the light emitting pattern EP are adjacent may have a stepped portion due to the inner side surface of the auxiliary electrode opening SE-OP which is not in contact with the light emitting pattern EP.

A cathode CE may entirely cover the top surface SE-US of the auxiliary electrode SE and the top surface EP-US the light emitting pattern EP. Here, as the region to which the auxiliary electrode SE and the light emitting pattern EP are adjacent has the stepped portion (e.g., due to the inner side surface of the auxiliary electrode opening SE-OP which is not in contact with the light emitting pattern EP), the cathode CE may also include a stepped portion likewise.

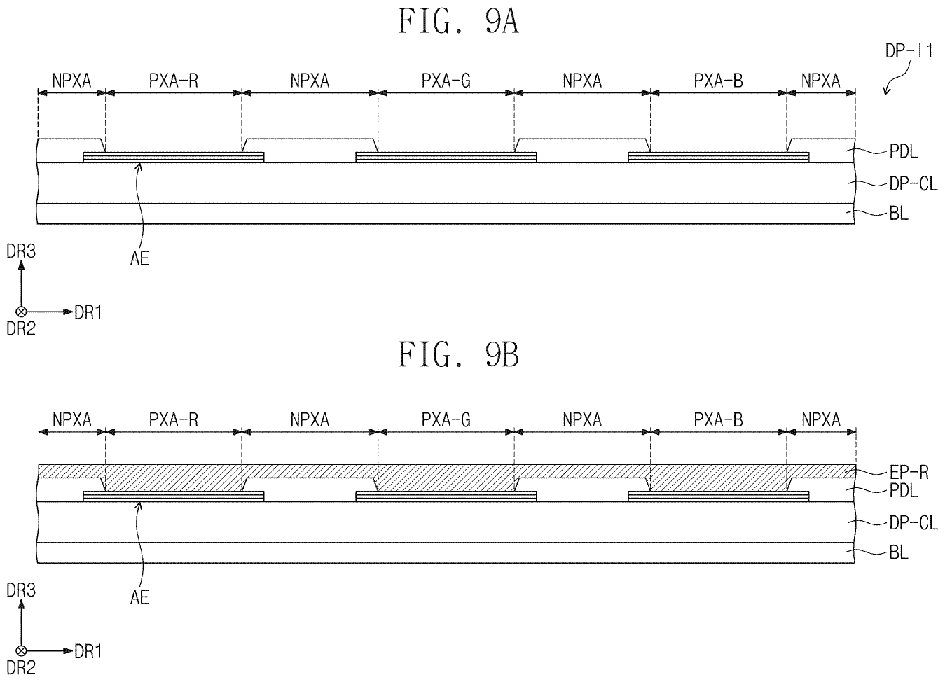

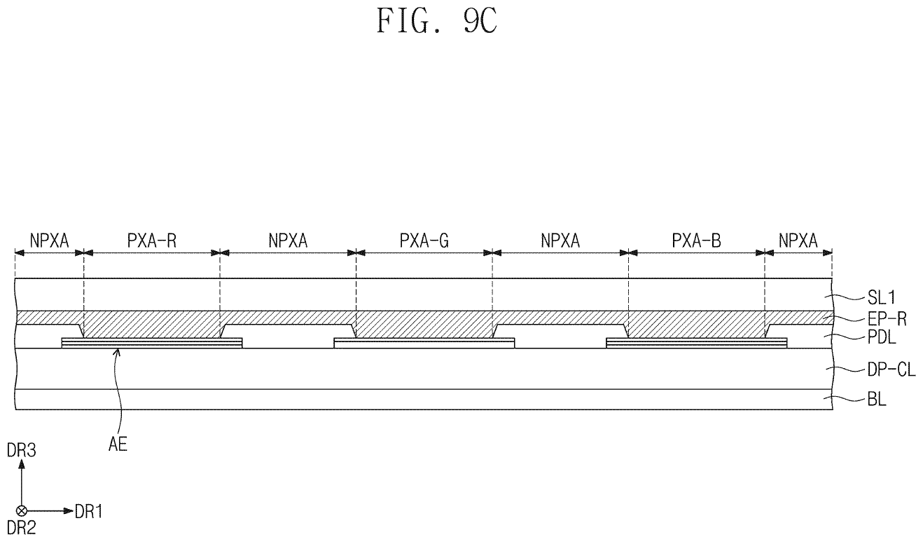

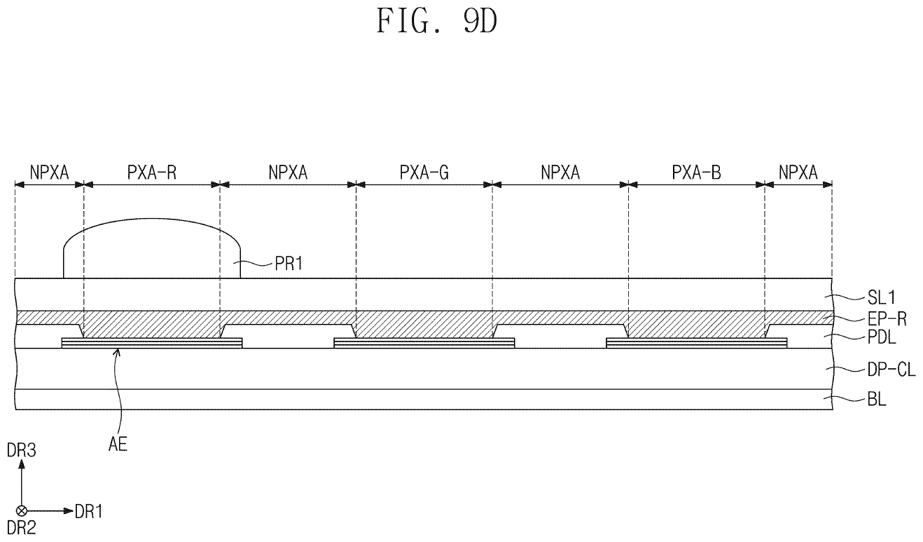

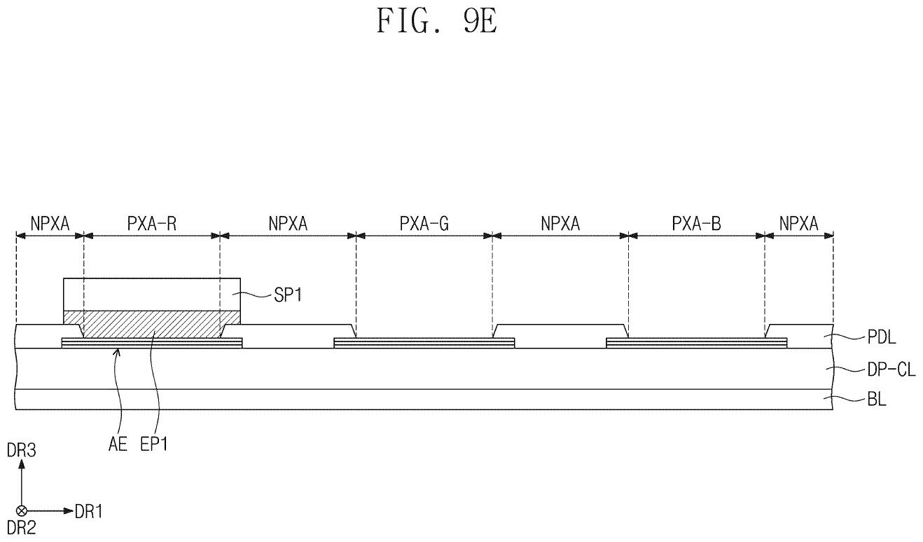

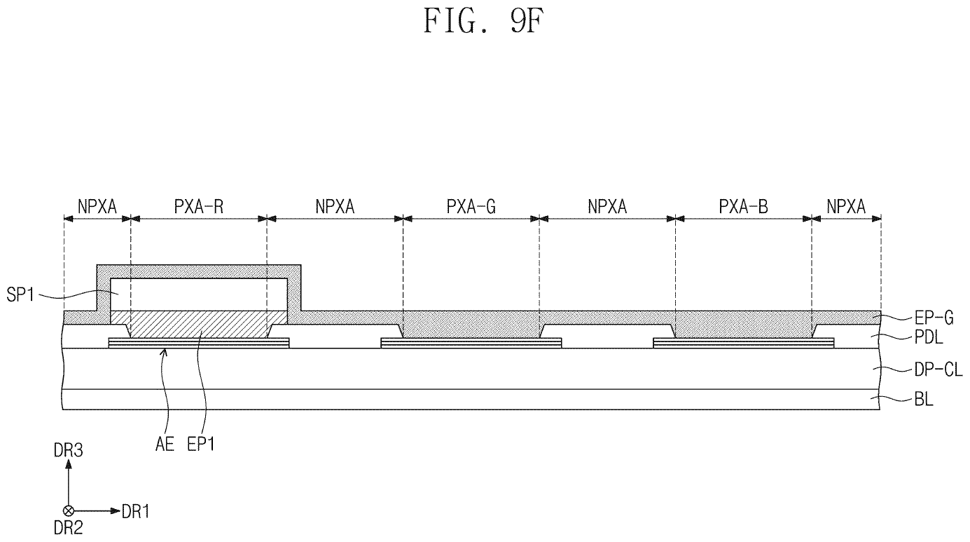

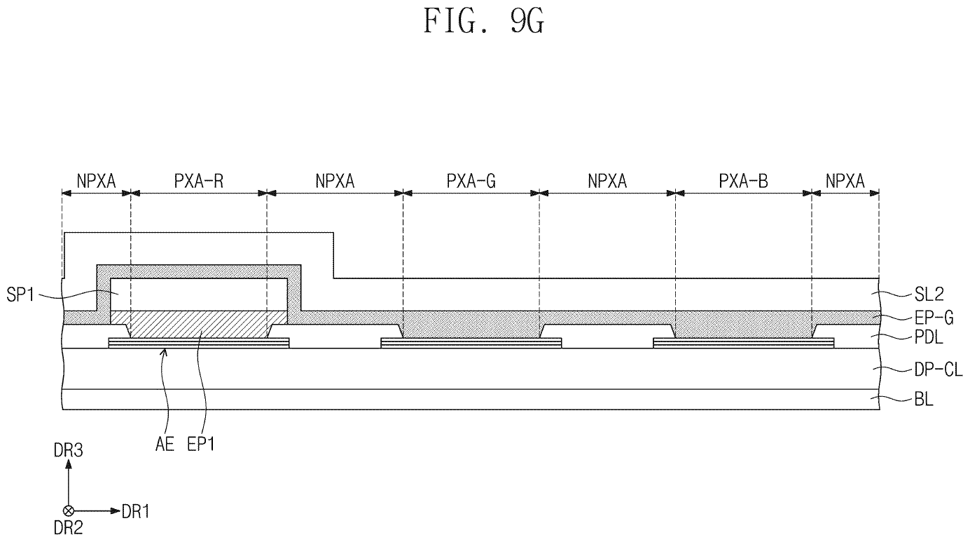

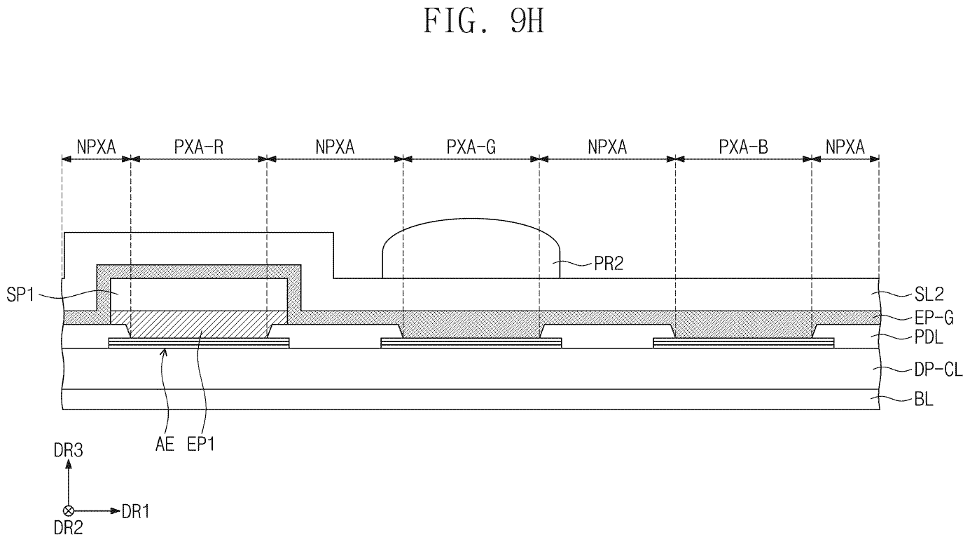

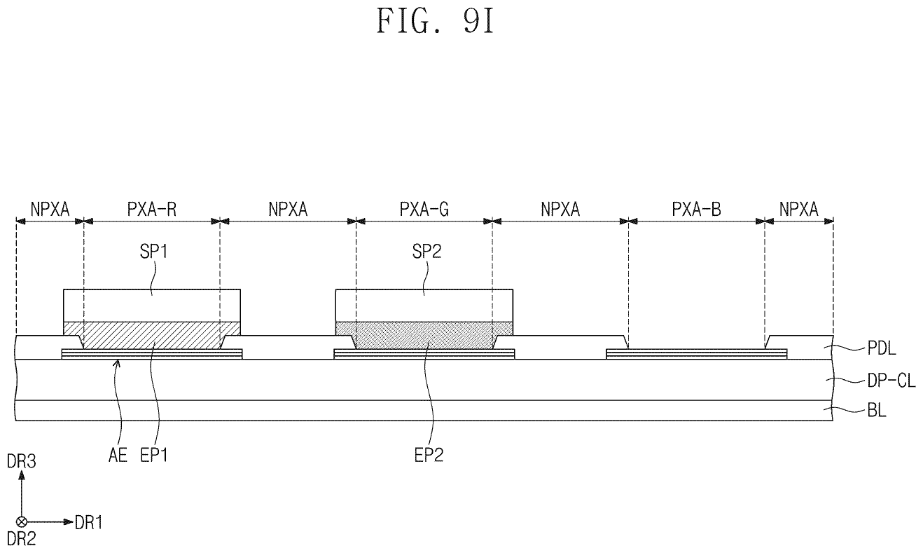

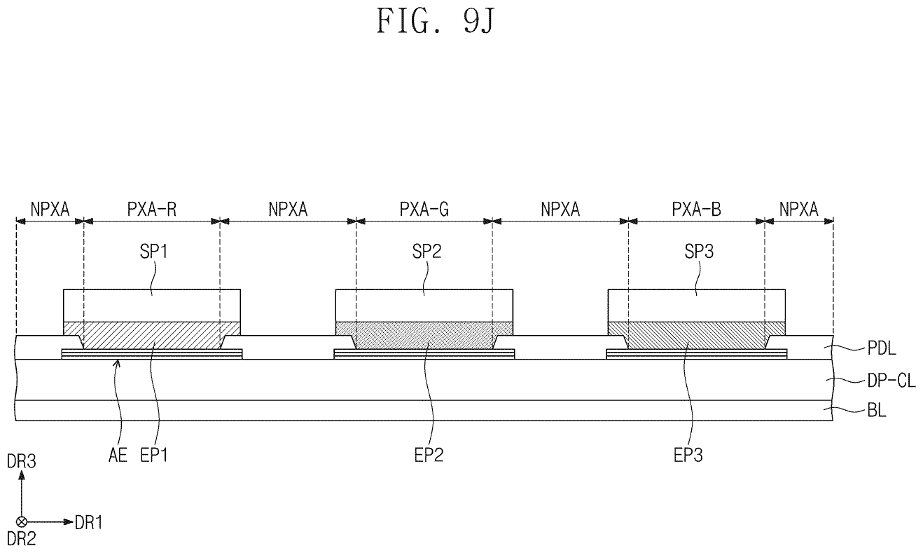

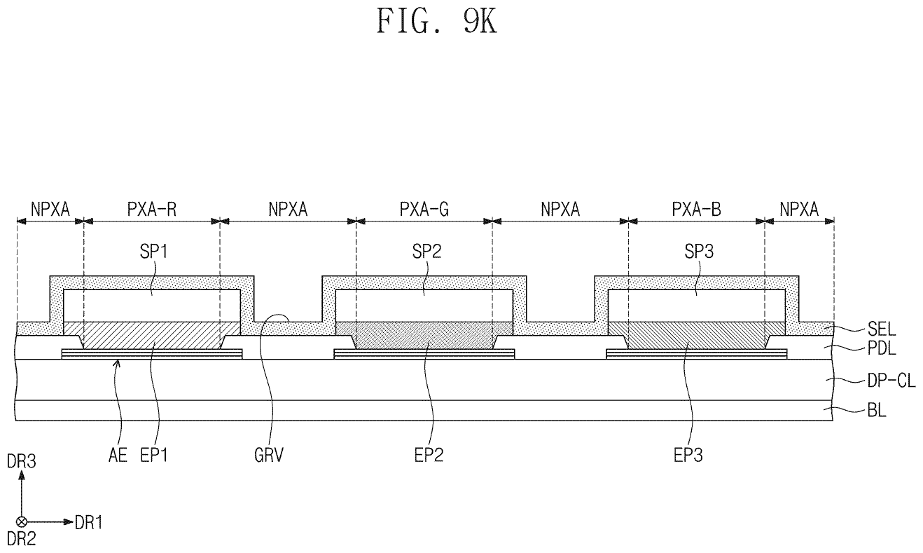

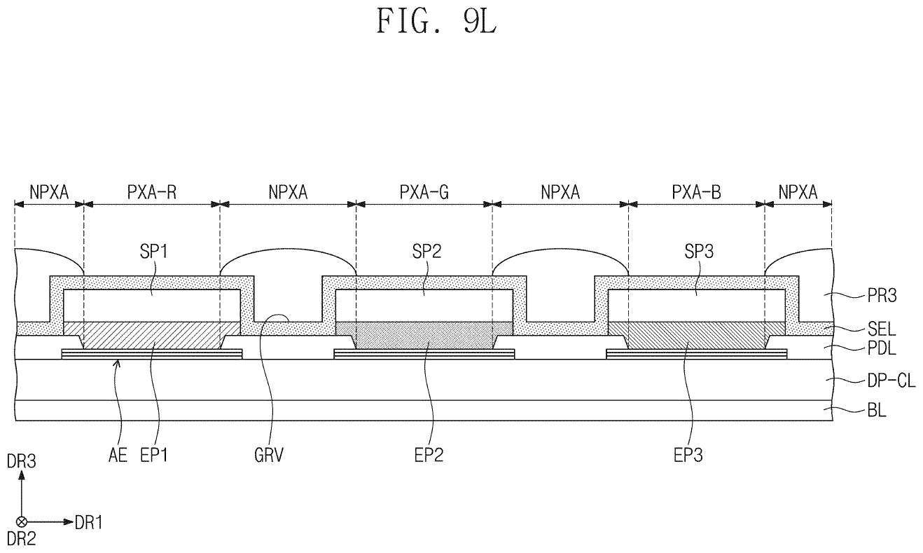

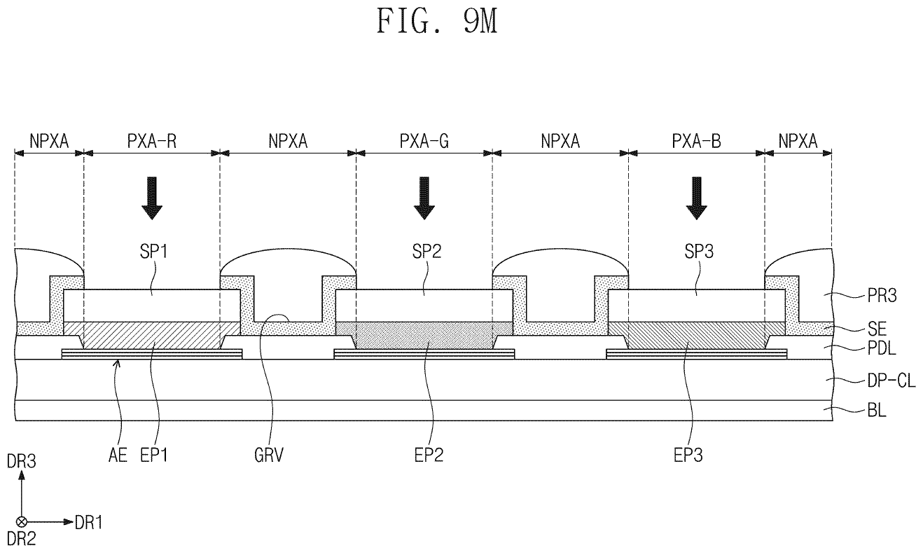

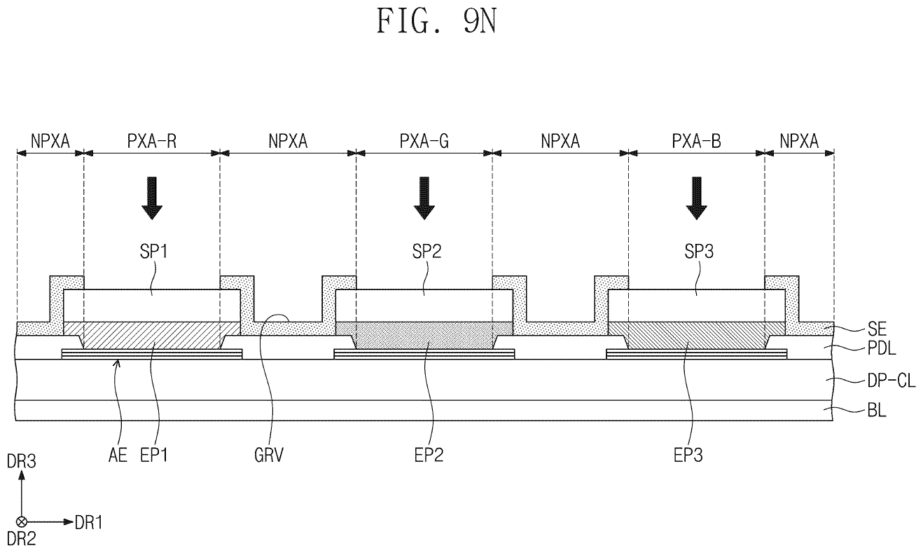

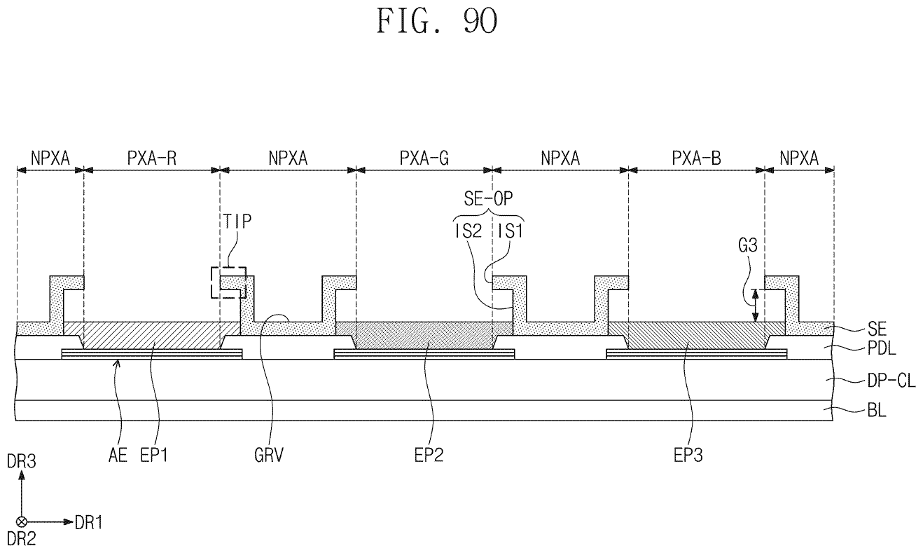

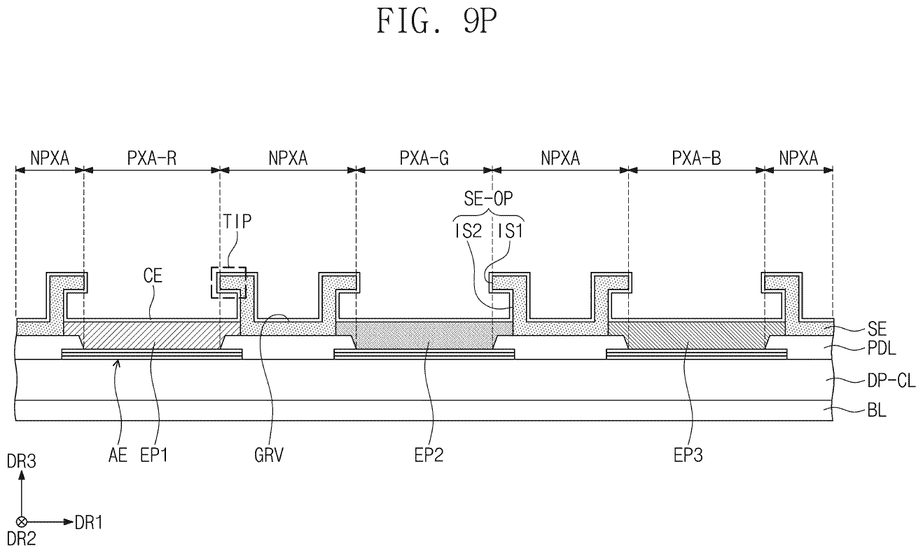

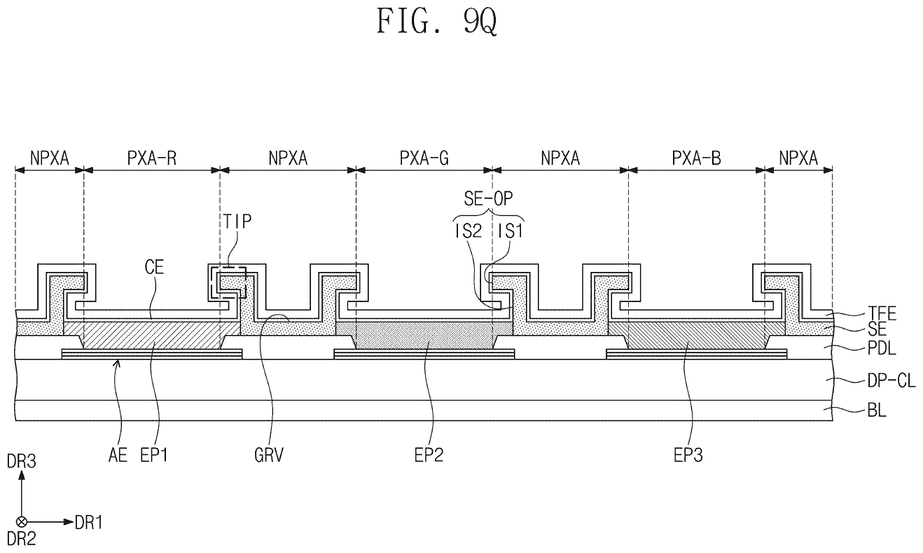

FIGS. 9A-9Q are views illustrating some of steps of a method for manufacturing a display panel DP according to one or more embodiments of the disclosure. One or more embodiments will be described with reference to FIGS. 9A-9Q by denoting the same/similar components as/to those described with reference to FIGS. 1 to 8 as the same/similar reference numbers or symbols, and avoiding redundant contents.

The display panel DP formed through the method described with reference to FIGS. 9A-9Q may correspond to the display panel DP in FIG. 6.

Referring to FIG. 9A, the method for manufacturing the display panel DP according to one or more embodiments of the disclosure may include providing a preliminary display panel DP-11. The preliminary display panel DP-11 provided in this embodiment may include a base layer BL, a circuit element layer DP-CL, an anode AE, and a pixel defining layer PDL.

The anode AE may be formed by stacking first to third conductive layers in sequence through a coating/deposition process and/or the like and then patterning the stacked conductive layers at a time (e.g., concurrently). For example, ITO, Al, and ITO layers may be deposited in sequence on a front surface of a circuit layer, and then be patterned through one mask to form the anode. However, this is illustrated as an example, and the number of layers constituting the anode AE is not limited.

In some embodiments, the circuit element layer DP-CL may be formed through a general or any suitable process for manufacturing a circuit element by forming an insulation layer, a semiconductor layer, and a conductive layer through a method such as coating and/or deposition, and then selectively patterning the insulation layer, the semiconductor layer, and the conductive layer through a photolithography process and an etching process to form a semiconductor pattern, a conductive pattern, a signal line, and/or the like.

Thereafter, referring to FIG. 9B, a first light emitting layer EP-R may be formed on the preliminary display panel DP-11.

Referring to FIG. 9C, a first sacrificial layer SL1 may be formed on the first light emitting layer EP-R. The first sacrificial layer SL1 may be formed by thermally evaporating a metal material. Accordingly, the first sacrificial layer SL1 may include a metal suitable for thermal evaporation. For example, the first sacrificial layer SL1 may include aluminum (Al), silver (Ag), gold (Au), and/or titanium (Ti). However, one or more embodiments are not limited thereto.

Referring to FIGS. 9D and 9E, the method for manufacturing the display panel DP according to one or more embodiments of the disclosure may include forming a first sacrificial pattern SP1 and a first light emitting pattern EP1. The first sacrificial layer SL1 and the first light emitting layer EP-R may be etched using a first photoresist layer PR1 as a mask to form the first sacrificial pattern SP1 and the first light emitting pattern EP1. Here, the forming of the first sacrificial pattern SP1 and the forming of the first light emitting pattern EP1 may be performed at the same time (e.g., concurrently). For example, the first sacrificial pattern SP1 and the first light emitting pattern EP1 may be patterned through one mask in one process.

The first sacrificial pattern SP1 may be patterned in a shape overlapping a first light emitting area PXA-R. The first light emitting layer EP-R may be patterned in substantially the same shape as the first sacrificial pattern SP1.

The first sacrificial pattern SP1 formed by etching the first sacrificial layer SL1 may overlap the first light emitting area PXA-R. The first light emitting pattern EP1 formed by etching the first light emitting layer EP-R may overlap the first light emitting area PXA-R. Both side surfaces of the first light emitting pattern EP1 may be aligned with both side surfaces of the first sacrificial pattern SP1, respectively.

Referring to FIG. 9F, a second light emitting layer EP-G may be formed on the first sacrificial pattern SP1, the pixel defining layer PDL, and the anode AE.

Referring to FIG. 9G, the method for manufacturing the display panel DP according to one or more embodiments of the disclosure may include forming a second sacrificial layer SL2 on the second light emitting layer EP-G.

The second sacrificial layer SL2 may include a metal suitable for thermal evaporation. For example, the second sacrificial layer SL2 may include aluminum (Al), silver (Ag), gold (Au), and/or titanium (Ti). However, one or more embodiments are not limited thereto.

Referring to FIGS. 9H and 91, the method for manufacturing the display panel DP according to one or more embodiments of the disclosure may include forming a second sacrificial pattern SP2 and a second light emitting pattern EP2. The second sacrificial layer SL2 and the second light emitting layer EP-G may be etched using a PR2 pattern as a mask to form the second sacrificial pattern SP2 and the second light emitting pattern EP2. Here, the forming of the second sacrificial pattern SP2 and the forming of the second light emitting pattern EP2 may be performed at the same time (e.g., concurrently). For example, the second sacrificial pattern SP2 and the second light emitting pattern EP2 may be patterned through one mask in one process.

The second sacrificial pattern SP2 may be patterned in a shape overlapping a second light emitting area PXA-G. The second light emitting layer EP-G may be patterned in substantially the same shape as the second sacrificial pattern SP2.

Referring to FIG. 9J, the method for manufacturing the display panel DP according to one or more embodiments of the disclosure may include forming a third sacrificial pattern SP3 and a third light emitting pattern EP3 through substantially the same process as that described above with reference to FIGS. 9B-91. A third sacrificial layer SL3 and a third light emitting layer EP-B may be etched using a PR pattern as a mask to form the third sacrificial pattern SP3 and the third light emitting pattern EP3. Here, the forming of the third sacrificial pattern SP3 and the forming of the third light emitting pattern EP3 may be performed at the same time (e.g., concurrently). For example, the third sacrificial pattern SP3 and the third light emitting pattern EP3 may be patterned through one mask in one process.

The third sacrificial pattern SP3 may be patterned in a shape overlapping a third light emitting area PXA-B. The third light emitting pattern EP3 may be patterned in substantially the same shape as the third sacrificial pattern SP3.

Respective top surfaces of the first sacrificial pattern SP1, the second sacrificial pattern SP2, and the third sacrificial pattern SP3 may be formed on the same layer (e.g., on the same level). Respective top surfaces of the first light emitting pattern EP1, the second light emitting pattern EP2, and the third light emitting pattern EP3 may be formed on the same layer (e.g., on the same level). However, one or more embodiments are not limited thereto.

Referring to FIG. 9K, the method for manufacturing the display panel DP according to one or more embodiments of the disclosure may include forming an auxiliary electrode layer SEL on the pixel defining layer PDL and the first to third sacrificial patterns SP1, SP2 and SP3. The auxiliary electrode layer SEL may be formed so as to entirely cover respective top surfaces of the pixel defining layer PDL and the first to third sacrificial patterns SP1, SP2 and SP3.

The auxiliary electrode layer SEL may be formed by depositing/coating a conductive material. For example, the conductive material may include a metal, a transparent conductive oxide (TCO), and/or a (e.g., any suitable) combination thereof. For example, the metal may include gold (Au), silver (Ag), aluminum (Al), magnesium (Mg), lithium (Li), molybdenum (Mo), titanium (Ti), copper (Cu), and/or an alloy. The transparent conductive oxide may include an indium tin oxide (ITO), an indium zinc oxide (IZO), a zinc oxide, an indium oxide, an indium gallium oxide, an indium gallium zinc oxide (IGZO), and/or an aluminum zinc oxide.

A groove GRV overlapping a peripheral region NPXA may be defined in a top surface of the auxiliary electrode layer SEL. The groove GRV may be a portion which is defined in the top surface of the auxiliary electrode layer SEL and recessed toward the pixel defining layer PDL. The groove GRV may be formed between the sacrificial patterns SP1, SP2 and SP3, and may be formed to overlap the pixel defining layer PDL on a plane.

Referring to FIGS. 9L and 9M, the method for manufacturing the display panel DP according to one or more embodiments of the disclosure may include forming a third photoresist layer PR3 on the auxiliary electrode layer SEL, etching the auxiliary electrode layer SEL by using the third photoresist layer PR3 as a mask, and removing the third photoresist layer PR3.

In the forming of the third photoresist layer PR3, the third photoresist layer PR3 may be formed by patterning a preliminary photoresist layer using as a photomask. The third photoresist layer PR3 may overlap the pixel defining layer PDL. The third photoresist layer PR3 may be arranged in the groove GRV defined in the top surface of the auxiliary electrode layer SEL. A portion of the third photoresist layer PR3 may overlap each of the first to third sacrificial patterns SP1, SP2 and SP3. As an example, FIG. 9L illustrates the portion of the third photoresist layer PR3 overlapping each of the first to third sacrificial patterns SP1, SP2 and SP3, but one or more embodiments of the disclosure are not limited thereto. For example, the third photoresist layer PR3 may overlap only the pixel defining layer PDL.

Referring to FIG. 9M, in the etching of the auxiliary electrode layer SEL, the auxiliary electrode layer SEL exposed by the third photoresist layer PR3 may be etched to form an auxiliary electrode SE. Here, the etching process may be performed as a dry etching or wet etching method. As the portion of the third photoresist layer PR3 overlaps each of the first to third sacrificial patterns SP1, SP2 and SP3, a portion of the top surface of each of the first to third sacrificial patterns SP1, SP2 and SP3 may be covered by the auxiliary electrode SE having not been etched.

Referring to FIGS. 9N and 9O, the method for manufacturing the display panel DP according to one or more embodiments of the disclosure may include removing the sacrificial patterns SP1, SP2 and SP3.

Referring to FIG. 9O, as the third photoresist layer PR3 and the first to third sacrificial patterns SP1, SP2 and SP3 are removed, the groove GRV and a tip TIP of the auxiliary electrode SE may be exposed.

Referring to FIG. 9O, as the first to third sacrificial patterns SP1, SP2 and SP3 are removed through the etching process, a second surface IS2 of an auxiliary electrode opening SE-OP, which corresponds to a side surface of each of the removed first to third sacrificial patterns SP1, SP2 and SP3, may be exposed. The tip TIP of the auxiliary electrode SE may be spaced and/or apart (e.g., spaced apart or separated) from the light emitting pattern EP due to the second surface IS2 of the auxiliary electrode opening SE-OP. A bottom surface of the tip TIP may be spaced a fixed distance G3 from a top surface EP-US the light emitting pattern EP.

A metal constituting the auxiliary electrode SE may have a different etch rate for a set or specific etchant (or etching gas) from a metal constituting the sacrificial patterns SP1, SP2 and SP3. For example, a material constituting the auxiliary electrode SE may have a set or predetermined etch selectivity to a material constituting the sacrificial patterns. For example, the auxiliary electrode SE may be formed of one or more suitable conductive materials such as copper (Cu), aluminum (Al), titanium (Ti), molybdenum (Mo), and/or indium tin oxide (ITO), as long as the conductive materials are materials each having an etch selectivity to the sacrificial patterns SP1, SP2 and SP3 (e.g., as long as the conductive material for the auxiliary electrode SE has a slower etch rate than the etch rate of the sacrificial patterns SP1, SP2 and SP3), and the auxiliary electrode SE is not limited to any one embodiment. For example, the metal used for the auxiliary electrode SE has a different etch rate compared to the metals used for the sacrificial patterns SP1, SP2, and SP3 when exposed to a specific etchant or etching gas. This means the material for the auxiliary electrode SE has a set etch selectivity relative to the sacrificial patterns. The auxiliary electrode SE may be made from one or more various suitable conductive materials such as copper (Cu), aluminum (Al), titanium (Ti), molybdenum (Mo), and/or indium tin oxide (ITO), provided these materials have a slower etch rate than the sacrificial patterns. The choice of material for the auxiliary electrode SE is not limited to a single embodiment.

Referring to FIG. 9P, the method for manufacturing the display panel DP according to one or more embodiments of the disclosure may include depositing a cathode CE on the respective top surfaces of the light emitting pattern EP and the auxiliary electrode SE. The cathode CE may entirely cover the top surfaces of the light emitting pattern EP and the auxiliary electrode SE. The cathode CE may cover both (e.g., simultaneously) a first surface IS1 and the second surface IS2 of the auxiliary electrode opening SE-OP. The tip TIP defined on the auxiliary electrode SE may be covered overall by the cathode CE.

In one or more embodiments, before the depositing of the cathode CE, the method for manufacturing the display panel DP according to one or more embodiments of the disclosure may further include a bake process of sufficiently or suitably heating the respective top surfaces of the light emitting pattern EP (e.g., the first to third light emitting patterns EP1 to EP3) and the auxiliary electrode SE. Accordingly, moisture, oxygen, and/or foreign matter such as dust particles on the top surfaces of the light emitting pattern EP and the auxiliary electrode SE may be removed to enable substantially uniform deposition of the cathode CE. The bake process may be performed below a glass transition temperature (Tg). The glass transition temperature (Tg) may refer to a temperature at which glass-liquid transition occurs.

Referring to FIG. 9Q, the method for manufacturing the display panel DP according to one or more embodiments of the disclosure may include forming an inorganic encapsulation film TFE on the cathode CE.

The inorganic encapsulation film TFE may protect a display element layer DP-OLED from moisture, oxygen, and/or foreign matter such as dust particles. The inorganic encapsulation film TFE may have a single-layer structure, or have a multilayer structure in which layers are stacked in the third direction DR3. For example, the inorganic encapsulation film TFE may include a single-layer inorganic film, or have a structure in which multilayer inorganic films are stacked. The inorganic encapsulation film TFE may protect the display element layer DP-OLED from moisture and/or oxygen. The inorganic encapsulation film TFE may include a silicon nitride layer, a silicon oxynitride layer, a silicon oxide layer, a titanium oxide layer, an aluminum oxide layer, and/or the like.

According to one or more embodiments of the disclosure, in the display panel which forms the light emitting element without using the metal mask, the metal layer may be utilized as the auxiliary electrode to decrease the resistance of the cathode in the display panel of the medium- and/or large-sized display, thereby reducing or preventing the unevenness in luminance of the panel. Here, the separate process may not need to be introduced to form the auxiliary electrode, thereby reducing the investment costs and the time consuming. Accordingly, the display panel with the improved display quality may be provided.

Although one or more embodiments of the present disclosure have been described, it is understood that the present disclosure should not be limited to these embodiments but one or more suitable changes and modifications can be made by one ordinary skilled in the art within the spirit and scope of the present disclosure as hereinafter claimed. Therefore, the technical scope of the disclosure is not limited to the contents described in the detailed description of the specification, but should be determined by the claims and their equivalents.

What is claimed is:

1. A display panel comprising:
a base layer;
a pixel defining layer on the base layer and in which a light emitting opening is defined;
an auxiliary electrode on the pixel defining layer and in which an auxiliary electrode opening overlapping the light emitting opening is defined; and
a light emitting element comprising an anode on the base layer and having at least a portion exposed by the light emitting opening;
a cathode on the auxiliary electrode and the anode; and
a light emitting pattern between the anode and the cathode and overlapping the light emitting opening,
wherein the auxiliary electrode and the light emitting pattern are in direct contact with each other.

2. The display panel of claim 1, wherein the cathode is in direct contact with the auxiliary electrode.

3. The display panel of claim 1, wherein the cathode entirely covers a top surface of the auxiliary electrode.

4. The display panel of claim 1, wherein the light emitting pattern is in the auxiliary electrode opening.

5. The display panel of claim 1, wherein a thickness of the auxiliary electrode is greater than a thickness of the cathode, and
the auxiliary electrode comprises at least one selected from among copper (Cu), aluminum (Al), titanium (Ti), molybdenum (Mo), indium tin oxide (ITO), and indium zinc oxide (IZO).

6. The display panel of claim 1, wherein the auxiliary electrode has higher conductivity than at least the cathode.

7. The display panel of claim 1, further comprising an inorganic encapsulation film on the cathode.

8. The display panel of claim 1, wherein the auxiliary electrode opening comprises a first surface and a second surface that have different widths in a cross-section,
wherein the first surface is on the second surface,
wherein the width of the second surface is greater than the width of the first surface.

9. The display panel of claim 8, wherein the first surface of the auxiliary electrode opening is spaced from the light emitting pattern.

10. The display panel of claim 8, wherein the light emitting pattern is in contact with a portion of the second surface.

11. The display panel of claim 8, wherein a groove overlapping the pixel defining layer is defined in a top surface of the auxiliary electrode.

12. The display panel of claim 8, wherein the first surface is a side surface of a tip protruding from the second surface toward a center of the auxiliary electrode opening,
wherein the tip overlaps the light emitting pattern.

13. The display panel of claim 1, wherein the display panel comprises a plurality of light emitting elements comprising the light emitting element, and the plurality of light emitting elements comprise a first light emitting element in which a first light emitting area that is to emit light having a first color is defined, a second light emitting element in which a second light emitting area that is to emit light having a second color different from the first color is defined, and a third light emitting element in which a third light emitting area that is to emit light having a third color different from the first color and the second color is defined,
wherein the display panel comprises a plurality of light emitting openings comprising the light emitting opening, and the plurality of light emitting openings comprise a first light emitting opening overlapping the first light emitting area, a second light emitting opening overlapping the second light emitting area, and a third light emitting opening overlapping the third light emitting area,
wherein the display panel comprises a plurality of auxiliary electrodes comprising the auxiliary electrode opening, and the plurality of auxiliary electrode openings comprise a first auxiliary electrode opening overlapping the first light emitting opening, a second auxiliary electrode opening overlapping the second light emitting opening, and a third auxiliary electrode opening overlapping the third light emitting opening.

14. A method comprising:
forming a preliminary pattern comprising an anode, a light emitting pattern, and a sacrificial pattern on a base layer;
forming an auxiliary electrode layer on a pixel defining layer and the sacrificial pattern;
forming a photoresist layer on the auxiliary electrode layer;
etching the auxiliary electrode layer to form an auxiliary electrode;
removing the photoresist layer;
removing the sacrificial pattern;
depositing a cathode on a top surface of each of the light emitting pattern and the auxiliary electrode; and
forming an inorganic encapsulation film on the cathode.

15. The method of claim 14, wherein, in the forming of the preliminary pattern, the sacrificial pattern is formed through the same process as the light emitting pattern.

16. The method of claim 14, wherein, in the forming of the preliminary pattern, a side surface of the sacrificial pattern and a side surface of the light emitting pattern are aligned with each other.

17. The method of claim 14, wherein, in the forming of the auxiliary electrode layer, a metal constituting the auxiliary electrode layer has a different etch rate from an etch rate of a metal constituting the sacrificial pattern.

18. The method of claim 14, wherein, in the forming of the photoresist layer, the photoresist layer overlaps the pixel defining layer.

19. The method of claim 18, wherein, in the forming of the photoresist layer, a portion of the photoresist layer overlaps the sacrificial pattern.

20. An electronic device for provide an image, the device comprising:
a display panel comprising:
a base layer;
a pixel defining layer on the base layer and in which a light emitting opening is defined;
an auxiliary electrode on the pixel defining layer and in which an auxiliary electrode opening overlapping the light emitting opening is defined; and
a light emitting element comprising an anode on the base layer and having at least a portion exposed by the light emitting opening, a cathode on the auxiliary electrode and the anode, and a light emitting pattern between the anode and the cathode and overlapping the light emitting opening,
wherein the auxiliary electrode and the light emitting pattern are in direct contact with each other.
